(19) United States
(12) Patent Application Publication
(10) Pub. No.: US 2025/0300080 A1
(43) Pub. Date: Sep. 25, 2025

(54) INTEGRATED CIRCUITS (ICs) HAVING SEPARATE SIGNAL AND POWER DISTRIBUTION NETWORK (PDN) INTERCONNECT STRUCTURES FOR REDUCED POWER SIGNAL ROUTING CONGESTION AND PATH LENGTHS, AND RELATED THREE-DIMENSIONAL (3D) ICs (3DICs) AND FABRICATION METHODS

(71) Applicant: QUALCOMM Incorporated, San Diego, CA (US)

(72) Inventors: Yue Li, San Diego, CA (US); Yangyang Sun, San Diego, CA (US); Darko Popovic, San Diego, CA (US); Durodami Lisk, San Diego, CA (US)

(21) Appl. No.: 18/609,314

(22) Filed: Mar. 19, 2024

(51) Int. Cl. H01L 23/528; H01L 21/768; H01L 23/48; H01L 23/522; H01L 25/065

(52) U.S. Cl. CPC H01L 23/5286; H01L 21/768; H01L 21/76898; H01L 23/481; H01L 23/5223; H01L 25/0657

(57) ABSTRACT

Integrated circuits (ICs) having a separate signal and power distribution network (PDN) interconnect structures for reduced power signal routing congestion and path lengths, and related three-dimensional (3D) ICs (3DICs) and fabrication methods. The IC includes a separate signal interconnect structure providing input/output (I/O) signal routing, and a PDN interconnect structure for providing power distribution signal routing. The signal interconnect structure is disposed on a first side of a semiconductor layer in the IC, and the PDN interconnect structure is disposed on a second side of the semiconductor layer opposite of the first side. In this manner, performance of semiconductor devices in the semiconductor layer can be improved, because power distribution signals do not have to be routed in a shared interconnect structure that is also used for routing I/O signals, which could otherwise congest and increase power distribution signal routing path lengths in the IC.

### BACKGROUND

### I. Field of the Disclosure

The field of the disclosure relates to integrated circuits (ICs)/semiconductor dies that include an interconnect structure with metallization layers for providing power and signal routing to devices formed in a semiconductor layer of the IC, and also three-dimensional ICs (3DICs) that include multiple, stacked dies.

### II. Background

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a substrate as a routing substrate (e.g., a package substrate) to provide physical support and an electrical interface to the die(s). The die(s) is electrically interfaced to metal interconnects (e.g., metal traces) exposed in an upper layer of the substrate as part of signal routing paths. The substrate also includes one or more metallization layers that include metal interconnects (e.g., metal traces, metal lines) with vertical interconnect accesses (vias) coupling the metal interconnects together between adjacent metallization layers to provide electrical interfaces between the dies. If the substrate is a package substrate, the substrate also includes a lower, outer metallization layer that includes metal interconnects coupled to external metal interconnects (e.g., ball grid array (BGA) interconnects) to provide an external interface between the dies in the IC package. The external metal interconnects can also be coupled (e.g., soldered) to traces in a printed circuit board (PCB) to attach the package to the PCB and interface its die(s) with the circuitry of the PCB.

Some IC packages are known as multiple (multi-) die IC packages, which include multiple dies included in the IC package for different purposes or applications. For example, a multi-die IC package may include a first, application die (e.g., a processor or system-on-a-chip (SoC), and separate second die that provides supporting circuits for the application die. Splitting major applications/functions into separate dies is an alternative to putting circuits for all such applications/functions into a single die. Fabrication cost and complexity increase disproportionally with larger sized dies. For example, the second die may have a die with a power management circuit modem, a processor, or memory as examples. These multi-die IC packages can be provided in the form of a three-dimensional (3D) IC (3DIC) package. For example, a 3DIC package can include a first bottom die coupled to a first, bottom package substrate, and a second, upper die that is stacked directly on the bottom die in a vertical direction. Through-silicon vias (TSVs) are disposed through the bottom die to provide signal routing paths to the upper die from the package substrate and/or the bottom die. These TSVs can not only provide signal routing paths to the second die, but can provide power signal routing paths to distribute power to a power distribution network (PDN) in an upper die(s) through the bottom die. However, this means that the power signal routing distance is greater for the upper die than the lower die, which can increase loop inductance and direct current (DC) losses in the PDN of the upper die.

### SUMMARY OF THE DISCLOSURE

Aspects disclosed herein include integrated circuits (ICs) having separate signal and power distribution network (PDN) interconnect structures for reduced power signal routing congestion and path lengths. Related three-dimensional (3D) ICs (3DICs) and fabrication methods are also disclosed. The IC includes a semiconductor die (“die”) that includes a semiconductor layer in which semiconductor devices are formed. The die also includes an interconnect structure that includes one or more metallization layers each having a metal layer with metal interconnects formed therein to provide signal routing paths within the die and to the semiconductor devices. In exemplary aspects, the IC includes a separate signal interconnect structure (e.g., as part of the die), and a separate PDN interconnect structure. The signal interconnect structure includes metallization layers with first metal interconnects for providing input/output (I/O) signal routing paths to the semiconductor devices. The PDN interconnect structure includes second metallization layers with second metal interconnects for providing power distribution signal routing paths as part of a PDN (i.e., power and ground signal paths) to the semiconductor devices for powering their operation. In an exemplary aspect, the signal interconnect structure is disposed on a first side of the semiconductor layer, and the PDN interconnect structure is disposed on a second side of the semiconductor layer opposite the first side of the semiconductor layer in a vertical direction. Through-silicon vias (TSVs) are disposed in the semiconductor layer and coupled to the signal and PDN interconnect structures to transfer power signals from the PDN interconnect structure to the signal interconnect structure and to transfer I/O signals from the signal interconnect structure to the PDN interconnect structure.

In this manner, semiconductor device performance in the IC can be improved. This is because power distribution signals do not have to be routed in a shared interconnect structure that is also used for routing I/O signals, which could otherwise congest and increase power distribution signal routing path lengths in the IC. This can facilitate the power distribution signal paths provided in the PDN interconnect structure and routed to the semiconductor devices to be reduced in length. Reducing power distribution signal routing path lengths reduces loop inductance and direct current (DC) power losses as a result. Providing a separate PDN interconnect structure in the IC can also facilitate minimizing capacitance routing path lengths between a decoupling capacitor(s) and the PDN in the PDN interconnect structure coupled to the semiconductor devices, thereby also reducing loop inductance for improved power noise filtering. Also, for example, by providing a separate PDN interconnect structure, a decoupling capacitor can more easily be integrated into the PDN interconnect structure (e.g., as a silicon capacitor (DTC) in a silicon layer in the PDN interconnect structure or a dielectric capacitor in a dielectric layer (e.g., silicon oxide layer)) due to the reduced routing congestion in the PDN interconnect structure. Integrating a capacitor in the PDN interconnect structure further reduces the capacitance routing path length between the decoupling capacitor(s) and the PDN as coupled to the semiconductor devices thereby further improving power noise filtering.

Also, by providing separate signal interconnect and PDN interconnect structures in the IC, each interconnect structure can be fabricated as a separate wafer as part of a wafer fabrication process and then coupled together, such as through a wafer-to-wafer (WoW) bonding process. This not only allows the signal interconnect and PDN interconnect structures to be fabricated separately, but also using different fabrication processes. For example, a lower, less expensive fabrication technology may be able to be used to fabricate the PDN interconnect structure, such as in the case that the pitch of metal interconnects in the PDN interconnect structure can be relaxed. A higher fabrication technology can then be used, if desired, to fabricate the signal interconnect structure, such as in the case that a reduced metal interconnect pitch is needed or desired to provide more efficient I/O signal routing for the die and in a smaller area. This can reduce the overall cost of fabricating the IC. As an example, the semiconductor layer of the die can be fabricated along with the signal interconnect structure as a back-end-of-line (BEOL) structure in a first wafer as part of a first wafer fabrication process. The PDN interconnect structure can be fabricated separately in a second wafer as part of a second wafer fabrication process. The first and second wafers with the respective separate signal interconnect and PDN interconnect structures can then be coupled together (e.g., through WoW bonding) to provide a single IC that includes the signal interconnect and PDN interconnect structures on opposites sides of the semiconductor layer in the first wafer. The combined first and second wafers can then be diced to form individual ICs each having the semiconductor layer with semiconductor devices formed therein surrounded on both sides by the separate signal interconnect and PDN interconnect structures.

In another exemplary aspect, a three-dimensional (3D) IC (3DIC) that can be provided as part of a 3DIC package. The 3DIC includes a first, bottom die that includes a semiconductor layer and an interconnect structure that can be coupled to a package substrate to provide signal routing paths between the package substrate and the first, bottom die. The 3DIC also includes a second, upper IC that is stacked on the first, lower die in a vertical direction. The second, upper IC includes separate signal interconnect and PDN interconnect structures like described above. TSVs are disposed in the semiconductor layer of the first, bottom die and coupled to the second, upper IC to provide signal routing paths from the interconnect structure of the first, bottom die and the second, upper IC. Power distribution signals and I/O signals can be routed through the TSVs in the first, bottom die to the second, upper IC. Power distribution signals can be routed to the PDN interconnect structure of the second, upper IC through couplings of the TSVs in the first, bottom die to the PDN interconnect structure adjacent to the first, bottom die. I/O signals can be routed through the PDN interconnect structure and through second TSVs in a second semiconductor layer of the second, upper die in the second, upper IC that are coupled to the signal interconnect structure on the opposite side of the second semiconductor layer from the PDN interconnect structure in the vertical direction. In this manner, the first, bottom die facilitates signal routing paths between the package substrate and the second, upper IC for power distribution signals and I/O signals. With the separate PDN interconnect structure provided in the second, upper IC and adjacent to the first, bottom die, the power distribution signal path lengths are reduced to reduce loop inductance and DC power losses, as discussed above.

Also, like discussed above, providing a separate PDN interconnect structure in the second, upper IC of the 3DIC can also facilitate minimizing capacitance routing path lengths between a decoupling capacitor(s) and the PDN in the PDN interconnect structure coupled to the semiconductor devices, thereby also reducing loop inductance for improved power noise filtering. A decoupling capacitor integrated in the PDN interconnect structure of the second, upper IC can allow efficient reduced length capacitance routing path length from the decoupling capacitor(s) to not only the PDN in the second, upper IC, but also to the PDN in the lower, bottom die (e.g., through signal routing through the TSVs in the lower, bottom die) which is adjacent to the PDN interconnect structure of the second, upper IC. Again, reducing the capacitance routing path length between the decoupling capacitor(s) and the PDNs in the first, bottom and second, upper IC further improves power noise filtering. Routing decoupling capacitance through the interconnects between the second, upper IC and the lower, bottom die can also avoid the need to provide land side capacitors (LSCs) and/or die side capacitors (DSC) that would involve larger capacitance routing path distances. Routing decoupling capacitance through the interconnects between the second, upper IC and the lower, bottom die can also eliminate the need for lateral offsetting of the second, upper IC from the first, bottom die in a first, horizontal direction to provide room for a decoupling capacitor(s) to be coupled to the PDN interconnect structure of the second, upper IC to avoid the increased length capacitance routing path distances from LSCs and/or DSCs.

In this regard, in one exemplary aspect, and IC is provided. The IC comprises a semiconductor layer comprising a first side and a second side opposite the first side, and a plurality of semiconductor devices. The IC also comprises a signal interconnect structure adjacent to the first side of the semiconductor layer. The signal interconnect structure comprises a plurality of first metal interconnects each configured to transfer an input/output (I/O) signal to a coupled first semiconductor device of the plurality of semiconductor devices. The IC also comprises a PDN interconnect structure adjacent to the second side of the semiconductor layer. The PDN interconnect structure comprises a plurality of second metal interconnects each configured to transfer a power signal. The IC also comprises a plurality of first vias each extending through the semiconductor layer and each coupled to a second metal interconnect of the plurality of second metal interconnects and the signal interconnect structure.

In another exemplary aspect, a method of fabricating an IC is provided. The method comprises forming a semiconductor layer comprising a first side and a second side opposite the first side. The method also comprises forming a plurality of semiconductor devices in the semiconductor layer. The method also comprises forming a plurality of first vias each extending through the semiconductor layer. The method also comprises forming a signal interconnect structure adjacent to the first side of the semiconductor layer, wherein forming the signal interconnect structure further comprises forming a plurality of first metal interconnects each configured to transfer an input/output (I/O) signal to a coupled first semiconductor device of the plurality of semiconductor devices. The method also comprises forming a PDN interconnect structure, wherein forming the PDN interconnect structure further comprises forming a plurality of second metal interconnects each configured to transfer a power signal. The method also comprises coupling the PDN interconnect structure adjacent to the second side of the semiconductor layer, coupling each second metal interconnect of the plurality of second metal interconnects to a first via of the plurality of first vias.

In another exemplary aspect, a three-dimensional (3D) integrated circuit (IC) (3DIC) is provided. The 3DIC comprises a first IC. The first IC comprises a first semiconductor layer comprising a first side and a second side opposite the first side, and a plurality of first semiconductor devices. The first IC also comprises a signal interconnect structure adjacent to the first side of the first semiconductor layer. The signal interconnect structure comprises a plurality of first metal interconnects each configured to transfer an I/O signal to a coupled first semiconductor device of the plurality of first semiconductor devices. The first IC also comprises a PDN interconnect structure adjacent to the second side of the first semiconductor layer. The PDN interconnect structure comprises a plurality of second metal interconnects each configured to transfer a power signal. The first IC also comprises a plurality of first vias each extending through the first semiconductor layer and each coupled to a second metal interconnect of the plurality of second metal interconnects and the signal interconnect structure. The 3DIC also comprises a second IC. The second IC comprises a second semiconductor layer. The second IC also comprises a third interconnect structure adjacent to the second semiconductor layer. The third interconnect structure comprises a plurality of third metal interconnects each comprising a power signal node. The second IC also comprises a plurality of second vias each extending through the second semiconductor layer and each coupled to a third metal interconnect of the plurality of third metal interconnects. The first IC is coupled to the second IC, by each of the plurality of second metal interconnects in the second IC being coupled to a second via of the plurality of second vias in the first IC, to couple each of the plurality of second metal interconnects to a third metal interconnect of the plurality of third metal interconnects in the second IC.

### BRIEF DESCRIPTION OF THE FIGURES

FIGS. 1A and 1B are a side view and close-up side view, respectively, of an exemplary three-dimensional (3D) integrated circuit (IC) (3DIC) that includes a first, bottom die that includes a semiconductor layer and an interconnect structure that can be coupled to a package substrate, and a second, upper IC stacked on the first, lower die in a second, vertical direction, wherein the second, upper IC includes separate signal interconnect and power distribution network (PDN) interconnect structures to reduce signal routing congestion and power signal routing path lengths for improved IC performance, and wherein decoupling capacitors are integrated into the PDN interconnect structure of the second, upper IC to provide decoupling capacitance to the PDNs in the second, upper IC and first, bottom die;

FIG. 2 is a side view of a 3D die structure for a 3DIC that includes a first, bottom die, and a second, upper die stacked on the first, bottom die in a vertical direction, wherein the first, bottom die includes through-silicon vias (TSVs) to provide signal routing paths through the first, bottom die to the second, upper die;

FIG. 3 is a side view of 3DIC package that includes a second, upper die stacked above and laterally offset from a first, bottom die to provide room for decoupling capacitors to be directly coupled to the second, upper die;

FIGS. 4A and 4B are a side view and close-up side view, respectively, of another exemplary IC having a single die that is similar to the second, upper die in the 3DIC in FIGS. 1A and 1B, respectively, with wafer-to-wafer (WoW) bonding of the signal interconnect structure and semiconductor layer, to the PDN interconnect structure with through metal bumps, and wherein decoupling capacitors are integrated in a silicon layer of the PDN interconnect structure as silicon capacitors;

FIGS. 5A and 5B are a side view and close-up side view, respectively, of another exemplary IC having a single die that is similar to the second, upper die in the 3DIC in FIGS. 1A and 1B, respectively, with WoW bonding of the signal interconnect structure and semiconductor layer, to the PDN interconnect structure with through metal bumps, and wherein decoupling capacitors are integrated in a dielectric layer of the PDN interconnect structure of the second, upper IC as dielectric capacitors;

FIG. 5C is a close-up side view of another IC package like the IC package in FIG. 5B, but with direct WoW bonding of the signal interconnect structure and semiconductor layer, to the PDN interconnect structure;

FIG. 6 is a flowchart illustrating an exemplary process of fabricating an IC that includes separate signal interconnect and PDN interconnect structures to reduce signal routing congestion and power signal routing path lengths for improved IC and die performance, and wherein decoupling capacitors can be integrated into the PDN interconnect structure of the IC to provide decoupling capacitance to the PDN in the IC, including, but not limited to, the ICs in FIGS. 1A-1B and 4A-5C;

FIGS. 7A-7C is a flowchart illustrating an exemplary process of separately fabricating a second wafer that includes a PDN interconnect structure that can be coupled to a first wafer with a semiconductor layer and signal interconnect structure to form a combined wafer that can be diced to form the IC in FIGS. 4A and 4B;

FIGS. 8A-8E are exemplary fabrication stages during fabrication of the PDN interconnect structure of the IC in FIGS. 4A-4B according to the exemplary fabrication process in FIGS. 7A-7C;

FIGS. 9A-9C is a flowchart illustrating an exemplary process of separately fabricating a first wafer that includes the semiconductor layer and signal interconnect structure that can be coupled to the second wafer in FIG. 8E to form a combined wafer that can be diced to form the IC in FIGS. 4A and 4B;

FIGS. 10A-10E are exemplary fabrication stages during fabrication of the semiconductor layer and signal interconnect structure of the IC in FIGS. 4A-5C according to the exemplary fabrication process in FIGS. 9A-9C;

FIG. 11 is a flowchart illustrating an exemplary process of coupling the separately fabricated second wafer with the PDN interconnect structure in FIG. 8E to the first wafer with the second semiconductor layer and signal interconnect structure in FIG. 10E to form a combined wafer that can be diced into separate ICs like the IC in FIGS. 4A and 4B.

FIGS. 12A and 12B are exemplary fabrication stages according to the exemplary process in FIG. 11;

FIGS. 13A-13C is a flowchart illustrating an exemplary process of separately fabricating the PDN interconnect structure for the IC in FIGS. 5A and 5B;

FIGS. 14A-14E are exemplary fabrication stages during fabrication of the PDN interconnect structure in FIGS. 5A and 5B according to the exemplary fabrication process in FIGS. 13A-13C;

FIG. 15 is a flowchart illustrating an exemplary process of coupling the separately fabricated semiconductor layer and signal interconnect structure in FIG. 10E to the separately fabricated PDN interconnect structure in FIG. 14E, to form the IC in FIGS. 5A and 5B;

FIGS. 16A and 16B are exemplary fabrication stages during coupling of the separately fabricated semiconductor layer and signal interconnect structure in FIG. 10E to the separately fabricated PDN interconnect structure in FIG. 14E, to form the IC in FIGS. 5A and 5B, according to the exemplary process in FIG. 15;

FIG. 17 is a block diagram of an exemplary wireless communications device that includes one or more IC packages that include an IC(s) that includes separate signal interconnect and PDN interconnect structures to reduce signal routing congestion and power signal routing path lengths for improved IC and die performance, and wherein decoupling capacitors can be integrated into the PDN interconnect structure of the IC to provide decoupling capacitance to the PDN in the IC, including, but not limited to, the ICs in FIGS. 1A-1B, 4A-5C, 12B and 16B, and that can be fabricated according to a fabrication process, including, but not limited to, the exemplary fabrication processes in FIGS. 6, 7A-7C, 9A-9C, 11, 13A-13C, and 15; and

FIG. 18 is a block diagram of an exemplary electronic device in the form of a processor-based system that includes one or more IC packages that include an IC(s) that includes separate signal interconnect and PDN interconnect structures to reduce signal routing congestion and power signal routing path lengths for improved IC and die performance, and wherein decoupling capacitors can be integrated into the PDN interconnect structure of the IC to provide decoupling capacitance to the PDN in the IC, including, but not limited to, the ICs in FIGS. 1A-1B, 4A-5C, 12B and 16B, and that can be fabricated according to a fabrication process, including, but not limited to, the exemplary fabrication processes in FIGS. 6, 7A-7C, 9A-9C, 11, 13A-13C, and 15.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include integrated circuits (ICs) having separate signal and power distribution network (PDN) interconnect structures for reduced power signal routing congestion and path lengths. Related three-dimensional (3D) ICs (3DICs) and fabrication methods are also disclosed. The IC includes a semiconductor die (“die”) that includes a semiconductor layer in which semiconductor devices are formed. The die also includes an interconnect structure that includes one or more metallization layers each having a metal layer with metal interconnects formed therein to provide signal routing paths within the die and to the semiconductor devices. In exemplary aspects, the IC includes a separate signal interconnect structure (e.g., as part of the die), and a separate PDN interconnect structure. The signal interconnect structure includes metallization layers with first metal interconnects for providing input/output (I/O) signal routing paths to the semiconductor devices. The PDN interconnect structure includes second metallization layers with second metal interconnects for providing power distribution signal routing paths as part of a PDN (i.e., power and ground signal paths) to the semiconductor devices for powering their operation. In an exemplary aspect, the signal interconnect structure is disposed on a first side of the semiconductor layer, and the PDN interconnect structure is disposed on a second side of the semiconductor layer opposite the first side of the semiconductor layer in a vertical direction. Through-silicon vias (TSVs) are disposed in the semiconductor layer and coupled to the signal and PDN interconnect structures to transfer power signals from the PDN interconnect structure to the signal interconnect structure and to transfer I/O signals from the signal interconnect structure to the PDN interconnect structure.

In this manner, semiconductor device performance in the IC can be improved. This is because power distribution signals do not have to be routed in a shared interconnect structure that is also used for routing I/O signals, which could otherwise congest and increase power distribution signal routing path lengths in the IC. This can facilitate the power distribution signal paths provided in the PDN interconnect structure and routed to the semiconductor devices to be reduced in length. Reducing power distribution signal routing path lengths reduces loop inductance and direct current (DC) power losses as a result. Providing a separate PDN interconnect structure in the IC can also facilitate minimizing capacitance routing path lengths between a decoupling capacitor(s) and the PDN in the PDN interconnect structure coupled to the semiconductor devices, thereby also reducing loop inductance for improved power noise filtering. Also, for example, by providing a separate PDN interconnect structure, a decoupling capacitor can more easily be integrated into the PDN interconnect structure (e.g., as a silicon capacitor (DTC) in a silicon layer in the PDN interconnect structure or a dielectric capacitor in a dielectric layer (e.g., silicon oxide layer)) due to the reduced routing congestion in the PDN interconnect structure. Integrating a capacitor in the PDN interconnect structure further reduces the capacitance routing path length between the decoupling capacitor(s) and the PDN as coupled to the semiconductor devices thereby further improving power noise filtering.

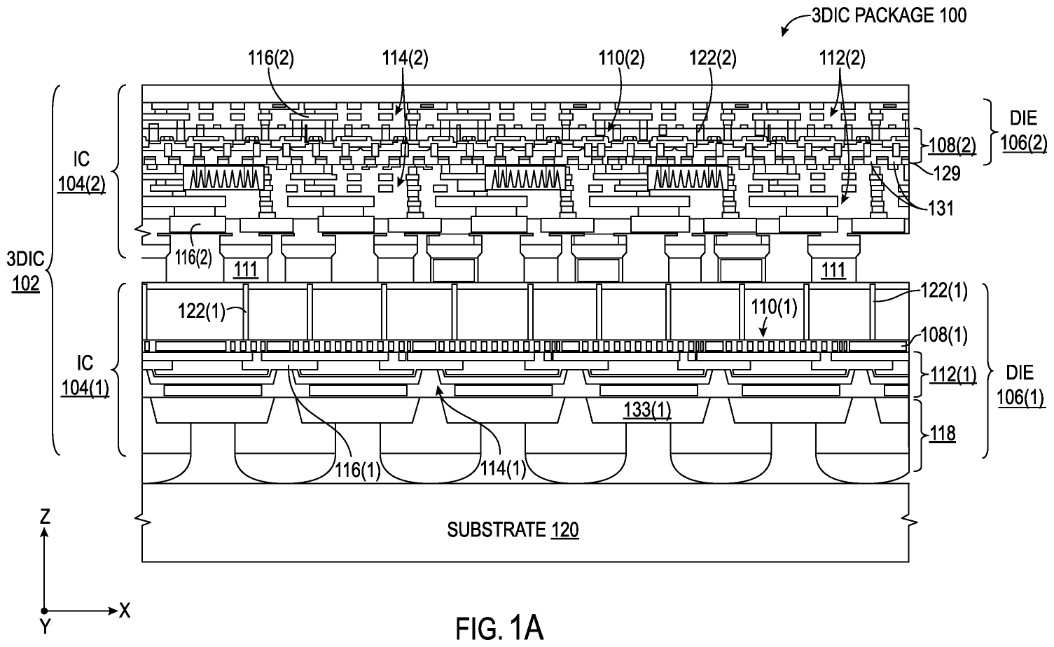

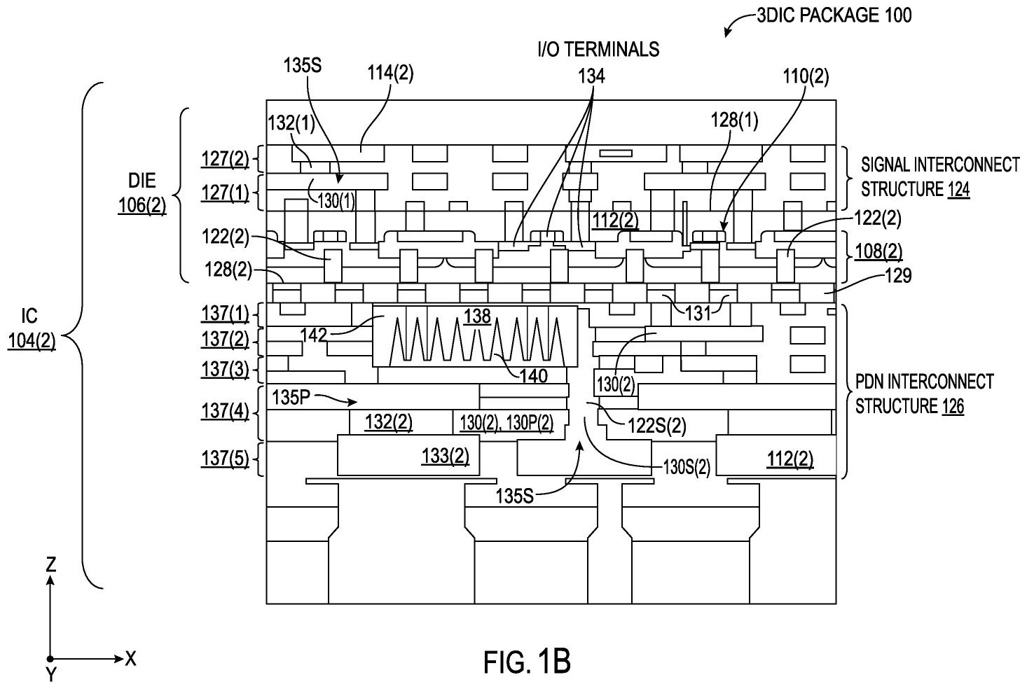

In this regard, FIGS. 1A and 1B are a side view and close-up side view, respectively, of an exemplary 3DIC package 100 that includes a 3DIC 102 that includes a first, bottom IC 104(1) that includes a first, bottom die 106(1) and a second, upper IC 104(2) that includes a second, upper die 106(2). A die includes a semiconductor layer in which semiconductor devices are formed. As shown in FIG. 1A, the footprint of the first, bottom IC 104(1) and the second, upper IC 104(2) extend in first, horizontal directions (X-axis and Y-axis directions). The 3DIC 102 is three-dimensional IC in that the second, upper IC 104(2) is disposed vertically adjacent to the first, upper IC 104(1) in a second, vertical direction (Z-axis direction) that is orthogonal to the first, horizontal directions (X-axis and Y-axis directions). In other words, the 3DIC 102 is built by vertically stacking the different ICs 104(1), 104(2) together into a single IC package as the 3DIC package 100 to conserve area of the 3DIC package 100. This allows each IC 104(1), 104(2) to be designed to provide specific functionality and to be fabricated and tested separately, but yet combined in a single vertical structure in an area-efficient manner to provide the 3DIC 102.

Each die 106(1), 106(2) of the respective IC 104(1), 104(2) includes a respective semiconductor layer 108(1), 108(2) in which semiconductor devices 110(1), 110(2) are formed. Each IC 104(1), 104(2) also has a respective metal interconnect structure 112(1), 112(2) (e.g., metal lines, metal traces) that each have metallization layers 114(1), 114(2) each having metal interconnects 116(1), 116(2) to provide signal routing paths in the dies 106(1), 106(2) to their semiconductor devices 110(1), 110(2), the other respective die 106(2), 106(1) for die-to-die (D2D) connections, and/or to external interconnects 118 (e.g., solder balls, ball grid array (BGA) interconnects) that can be coupled to a substrate 120 (e.g., a package substrate 120 (e.g., an embedded trace substrate (ETS), a modified semi-additive process (mSAP) substrate)), for external signal routing with the 3DIC package 100. Signal interconnections are provided between the ICs 104(1), 104(2) through first through-silicon vias (TSVs) 122(1) that are disposed through a first semiconductor layer 108(1) of the first, bottom die 106(1) extending in the second, vertical direction (Z-axis direction) to provide signal through paths through the first, bottom die 106(1) to the second, upper die 106(2). As shown in FIG. 1A, the first TSVs 122(1) in the first, bottom IC 104(1) are coupled to the second, upper IC 104(2) through metal interconnects 111 (e.g., solder bumps, ball grid array (BGA) interconnects) to electrically and physically couple the second, upper IC 104(2) to the first, bottom IC 104(1).

As shown in the close-up side partial view of the 3DIC package 100 in FIG. 1B, and as discussed in more detail below, the second, upper IC 104(2) in the 3DIC 102 in this example includes a metal interconnect structure 112(2) that includes a separate signal interconnect structure 124 and PDN interconnect structure 126. This reduces signal routing congestion and power signal routing path lengths in the second, upper IC 104(2) for improved performance of the second, upper IC 104(2) and its second, upper die 106(2). For example, as discussed in more detail below, the signal interconnect structure 124 may be fabricated as part of a back-end-of-line (BEOL) process adjacent to or on a first side 128(1) of the second semiconductor layer 108(2) as part of a first wafer in the second, vertical direction (Z-axis direction). In this example, the second, upper die 106(2) is a semiconductor die by its inclusion of the semiconductor layer 108(2) and the signal interconnect structure 124. The PDN interconnect structure 126 does not include a semiconductor layer in which semiconductor devices are formed in this example. However, the PDN interconnect structure 126 may be fabricated separately as part of a second, separate wafer and coupled to or disposed adjacent to a second side 128(2) of the semiconductor layer 108(2) opposite the first side 128(1) in the second, vertical direction (Z-axis direction). Note that alternatively, the PDN interconnect structure 126 could be included as part of a die that also includes a semiconductor layer in which semiconductor devices are formed, and the signal interconnect structure 124 could be fabricated as not including a semiconductor layer.

As shown in FIG. 1B, the combined second semiconductor layer 108(2) and signal interconnect structure 124 can be coupled to the separate PDN interconnect structure 126 through a metal bump layer 129 (e.g., from a wafer-on-wafer (WoW) bonding process in fabrication) that includes a plurality of metal bumps 131 interconnected between exposed second TSVs 122(2) extending through the second semiconductor layer 108(2) in the second, vertical direction (Z-axis direction) and adjacent to the PDN interconnect structure 126, and exposed second metal interconnects 130(2) in the PDN interconnect structure 126. Note that alternatively, the combined second semiconductor layer 108(2) and signal interconnect structure 124 could be coupled to the separate PDN interconnect structure 126 by a direct coupling or bonding the exposed second TSVs 122(2) from the second semiconductor layer 108(2) to the exposed second metal interconnects 130(2) in the PDN interconnect structure 126. The signal interconnect structure 124 of the second, upper die 106(2) is designed with first metallization layers 127(1) that have metal interconnects 130(1) interconnected by first vias 132(1) extending in the second, vertical direction (Z-axis direction). These interconnected first metal interconnects 130(1) and first vias 132(1) provide input/output (I/O) signal routing paths for transferring I/O signals 135S to I/O terminals 134 of the second semiconductor devices 110(2) formed in the second semiconductor layer 108(2) of the second, upper die 106(2). The I/O signals 135S are not power signals for providing power for operation of a second semiconductor device 110(2) in this example. The I/O signals 135S are input signals used for controlling operation of a coupled second semiconductor device 110(2) as part of a circuit and/or output signals carrying a response signal generated by a coupled second semiconductor device 110(2) based on its operation as part of a circuit. The I/O signals 135S could be, for example, control signals, communication signals, sensor signals, etc. related to a circuit formed by a coupled second semiconductor device 110(2). For example, the I/O terminals 134 can be a source contact, drain contact, and/or gate contacts that are coupled to a respective source, drain, and gates of the second semiconductor devices 110(2).

The PDN interconnect structure 126 includes second metallization layers 137(1)-137(5) with second metal interconnects 130(2) interconnected by second vias 132(2) extending in the second, vertical direction (Z-axis direction). Interconnected second metal interconnects 130(2) and second vias 132(2) provide power distribution signal routing paths (i.e., power and ground signal paths) for routing of power signals 135P as part of a second PDN 133(2) in the second, upper IC 104(2) to the second semiconductor devices 110(2) for powering their operation. The power signals 135P are voltage signals with respect to a power node or ground node that can provide energy/power to operate a coupled second semiconductor device 110(2). Second TSVs 122(2) are disposed in the second semiconductor layer 108(2) in the second, vertical direction (Z-axis direction) and coupled to the signal and PDN interconnect structures 124, 126 to transfer power signals from the PDN interconnect structure 126 to the die 106(2) and to transfer I/O signals from the signal interconnect structure 124 to the PDN interconnect structure 126.

In this manner, I/O and power signals 135S, 135P can be transferred through the first TSVs 122(1) in the first, bottom IC 104(1) that are coupled, through the metal interconnects 111 (see FIG. 1A), to the second metal interconnects 130(2) in the PDN interconnect structure 126 to the second, upper IC 104(2). The first, bottom IC 104(1) facilitates the providing of power signals (voltage signals, i.e., power and ground signals) to the second, upper IC 104(2) for distribution in its PDN interconnect structure 126 for routing and distribution to the second semiconductor devices 110(2). The power signals 135P can be transferred from the second TSVs 122(2) that are coupled to the second metal interconnects 130(2), as power signal nodes 130P(2) (i.e., power and ground terminals or planes) in the PDN interconnect structure 126, to be distributed to the second semiconductor devices 110(2) through interconnections between the second metal interconnects 130(2) interconnected by the second vias 132(2) and the second semiconductor devices 110(2). For example, the 3DIC package 100 may be coupled through the external interconnects 118 to a power source, such as a power management IC (PMIC) that is configured to supply power through power signals routed through the substrate 120 (e.g., as a package substrate). The power signals transferred on the external interconnects 118 are coupled to the first metal interconnects 116(1) as part of a first PDN 133(1) in the metal interconnect structure 112(1) of the first, bottom die 106(1), as shown in FIG. 1A, which can then be transferred through coupled first TSVs 122(1), through the metal interconnects 111, to the second metal interconnects 130(2) of the PDN interconnect structure 126 of the second, upper IC 104(2) to be routed to the second semiconductor devices 110(2).

With continuing reference to FIG. 1B, the first, bottom IC 104(1) also facilitates the providing of I/O signals to the second, upper IC 104(2) that can then be routed to the signal interconnect structure 124 through the second TSVs 122(2) for routing and distribution of the I/O signals to the second semiconductor devices 110(2). The I/O signals can be transferred from the second TSVs 122(2) that are coupled to second metal interconnects 130S(2) interconnected by second vias 122S(2) that are each dedicated for I/O signal transfer in the PDN interconnect structure 126, to coupled first metal interconnects 130(1) in the signal interconnect structure 124. These I/O signal dedicated second metal interconnects 130S(2) and second vias 122S(2) are not coupled to other metal interconnects 130(2) that form power signal nodes 130P(2) that are configured to transfer power signals in this example. These I/O signals can then be routed and transferred from the first metal interconnects 130(1) in the signal interconnect structure 124 to the second semiconductor devices 110(2). In this manner, the performance of the second semiconductor devices 110(2) in the second, upper die 106(2) can be improved. This is because power distribution signals do not have to be routed in a shared interconnect structure that is also used for routing I/O signals, which could otherwise congest and increase power distribution signal routing path lengths in the second, upper IC 104(2). This can facilitate the power distribution signal paths provided in the PDN interconnect structure 126 and routed to the second semiconductor devices 110(2) to be reduced in length. Reducing power distribution signal routing path lengths reduces loop inductance and direct current (DC) power losses in power signals as a result.

As also shown in FIG. 1B and discussed in more detail below, providing a separate PDN interconnect structure 126 in the second, upper IC 104(2) can also facilitate minimizing capacitance routing path lengths between a decoupling capacitor(s) 138 provided in the PDN interconnect structure 126, thereby also reducing loop inductance for improved power noise filtering. In this example, decoupling capacitors 138 are disposed in the PDN interconnect structure 126 and coupled to the second PDN 133(2) in the second, upper IC 104(2) provided therein by being coupled to a second metal interconnect(s) 130(2) that is interconnected by the second vias 132(2) and coupled to the second semiconductor devices 110(2) to power their operation. In this example, the decoupling capacitors 138 are integrated into the separate PDN interconnect structure 126. Providing a separate PDN interconnect structure 126 in the second, upper IC 104(2) may more easily facilitate the integration of the decoupling capacitors 138 into the PDN interconnect structure 126 and thus the second, upper IC 104(2), because there is reduced I/O signal routing in the PDN interconnect structure 126 as a result of providing the separate signal interconnect structure 124 in the second, upper IC 104(2). This in turn provides shorter capacitance signal routing paths between the capacitor 138 and the second PDN 133(2) in the second, upper IC 104(2). In another example, by the capacitor 138 provided in the PDN interconnect structure 126 of the second, upper IC 104(2) being coupled to second metal interconnects 130(2) as power signal nodes 130P(2) in the first, lower IC 104(1) to receive power signals 135P, the capacitor 138 can also conveniently provide a decoupling capacitance to the first PDN 133(1) in the first, lower IC 104(1). This may avoid or reduce the need for a die side capacitor (DSC) or land side capacitor (LSC) that will have longer capacitance signal routing paths to the first, lower IC 104(1) as well as the second, upper IC 104(2) due to the routing through the substrate 120.

In this example, a cavity 140 is formed in the second metallization layers 137(1)-137(2) in which the capacitor 138 can be disposed to be integrated within the PDN interconnect structure 126. For example, the capacitor 138 may be a silicon capacitor (e.g., a deep trench capacitor (DTC)) that is formed in a silicon layer 142 as a separate device that can then be inserted into the cavity 140 and interconnected to second metal interconnects 130(2) in the PDN interconnect structure 126 to be coupled to the second PDN 133(2). As discussed in more detail below, the capacitor 138 could also be formed in a separate dielectric layer (e.g., a silicon oxide layer) in the PDN interconnect structure 126 that is not shown in the 3DIC 102 in FIGS. 1A and 1B. The capacitor 138 could also be directly coupled to terminals of the second semiconductor devices 110(2) that are coupled to power signal nodes 130P(2) in the second metal interconnects 130(2) to couple the capacitor 138 to the second PDN 133(2).

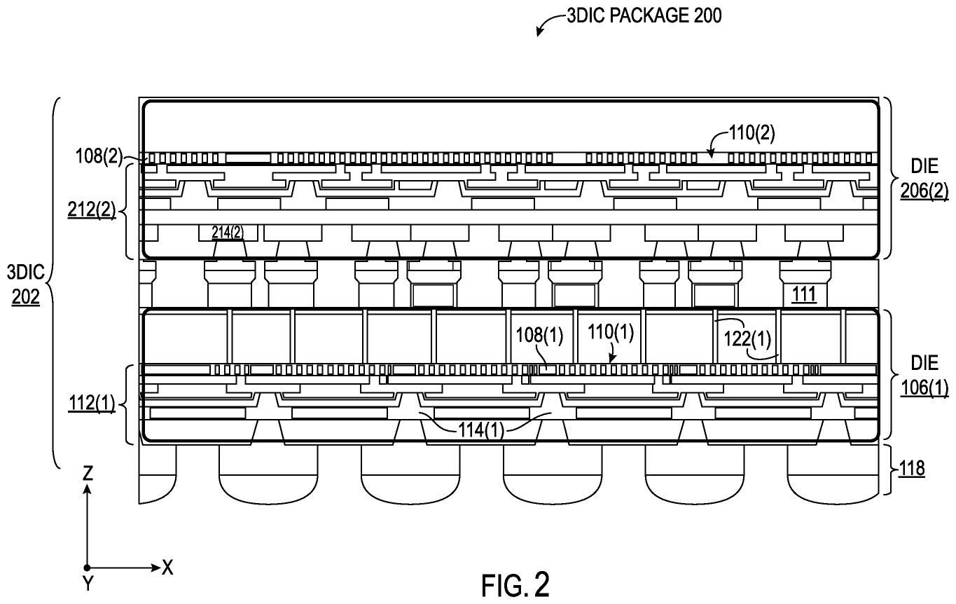

The 3DIC 102 in FIGS. 1A and 1B is contrasted with a 3DIC 202 in a 3DIC package 200 in FIG. 2 that has an upper, second die 206(2) that does not include separate signal and PDN interconnect structures like the separate signal interconnect structure 124 and PDN interconnect structure 126 in the 3DIC 102. As shown in the side view of the 3DIC 202 in FIG. 2, the same first, bottom die 106(1) is provided with common elements shown with common element numbers with FIGS. 1A and 1B. The second, upper die 206(2) is disposed vertically adjacent to the first, bottom die 106(1) in the second, vertical direction (Z-axis direction) and coupled to the first, lower die 106(1) through metal interconnects 111. The second, upper die 206(2) has the second semiconductor layer 108(2) that is included in the second, upper die 106(2) in the 3DIC 102 in FIGS. 1A and 1B. However, the second, upper die 206(2) only has one interconnect structure 212(2) that has metal interconnects 214(2) for routing all of the I/O signals and power signals to the second semiconductor devices 110(2) and the first, lower die 106(1). This may provide increased signal routing congestion in the single interconnect structure 212(2) that may make it more difficult to provide enough signal routing density in the second, upper die 206(2) without otherwise increasing the footprint of the first, bottom die 106(1) and the second, upper die 206(2). Further, providing the single interconnect structure 212(2) in the second, upper die 206(2) may make it more difficult to provide decoupling capacitors in the second interconnect structure 212(2) to conveniently provide a decoupling capacitance in the 3DIC 202.

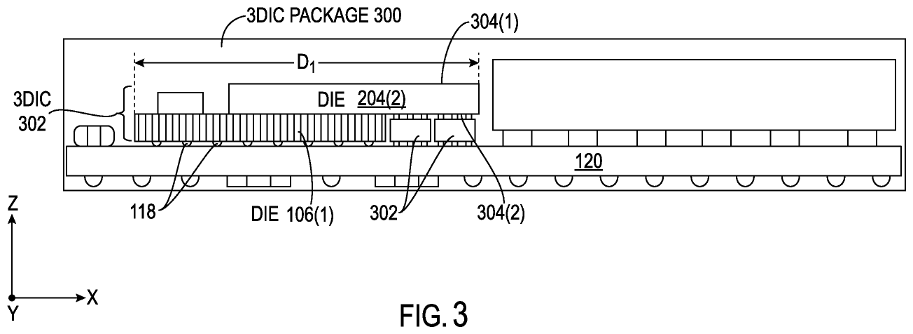

As shown in another exemplary 3DIC package 300 in FIG. 3, the second, upper die 206(2) could be laterally offset in the first, horizontal direction(s) (X-axis and/or Y-axis directions) from the first, bottom die 106(1) to provide room for a decoupling capacitor 302 to be directly coupled to a non-overlapping, second side 304(2) of the second, upper die 206(2) opposite of the first side 304(1) of the second upper die 206(2) in the second, vertical direction (Z-axis direction). In this manner, the decoupling capacitor 302 would be more closely located to the second, upper die 206(2) to reduce the capacitance signal routing paths from the decoupling capacitor 302 to the second, upper die 206(2) and/or the first, bottom die 106(1) as opposed to a DSC or LSC to provide decoupling capacitance. However, as shown in FIG. 3, this increases the lateral distance D1 and thus the lateral area of the 3DIC 302, thus increasing the overall size of the 3DIC package 300, which may not be desirable or feasible for an intended application of the 3DIC package 300.

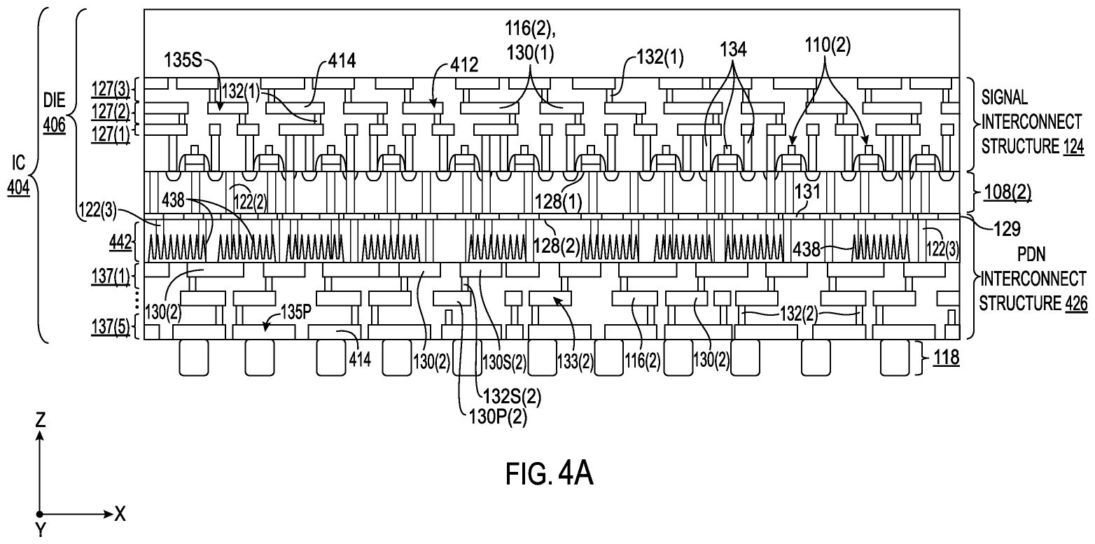

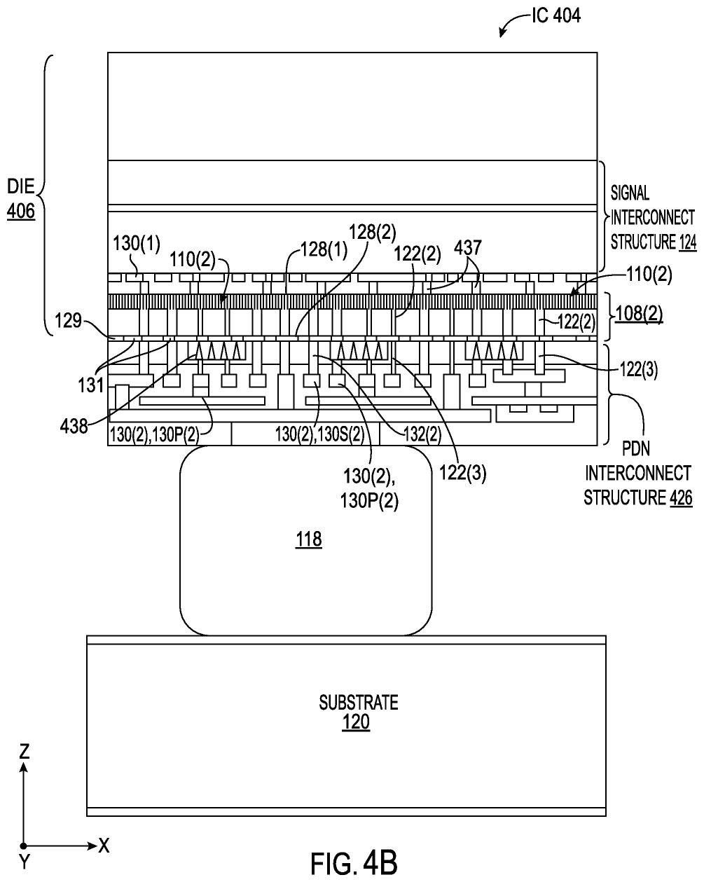

FIGS. 4A and 4B are a side view and close-up side view, respectively, of another exemplary IC package 400 that includes an IC 404 that includes a die 406 that also includes the separate signal interconnect structure 124. The IC 404 also includes the separate PDN interconnect structure 426 to reduce signal routing congestion and power signal routing path lengths in the IC 404 for improved performance of the die 406. The die 406 can be included as the second, upper die 106(2) in the 3DIC 102 in FIGS. 1A and 1B as a non-limiting example. Common elements between the die 406 in FIGS. 4A and 4B and the second, upper die 106(2) in FIGS. 1A and 1B are shown with common element numbers. As discussed below, in this example IC 404, the PDN interconnect structure 426 is similar to the PDN interconnect structure 126 of the second, upper IC 104(2) in the 3DIC 102 in FIGS. 1A and 1B, but the PDN interconnect structure 426 includes a separate silicon layer 442 that has capacitors 438 disposed therein to provide the capacitors 438 as silicon capacitors.

In this example, the die 406 is a semiconductor die by its inclusion of the semiconductor layer 108(2) and the signal interconnect structure 124. The PDN interconnect structure 426 does not include a semiconductor layer in which semiconductor devices are formed in this example. However, note that alternatively, the PDN interconnect structure 426 could be included as part of a die that also includes a semiconductor layer in which semiconductors devices are formed, and the signal interconnect structure 124 could be fabricated as not including a semiconductor layer.

With reference to FIG. 4A, the footprint of the IC 404 and its die 406 extends in first, horizontal directions (X-axis and Y-axis directions). The die 406 includes the second semiconductor layer 108(2) in which the second semiconductor devices 110(2) are formed like described for the 3DIC 102 in FIGS. 1A and 1B. The die 406 also has respective metal interconnect structures 412 (e.g., metal lines, metal traces) that have metallization layers 414 each having metal interconnects 116(2) to provide signal routing paths in the die 406 to their second semiconductor devices 110(2). As shown in FIG. 4A and the close-up side partial view of the IC 404 in FIG. 4B, the IC 404 includes the separate signal interconnect structure 124 of the die 406 and the PDN interconnect structure 426 to reduce signal routing congestion and power signal routing path lengths in the IC 404 for improved performance of the second semiconductor devices 110(2). The I/O and power signals 135S, 135P can be transferred from the second metal interconnects 130(2) in the PDN interconnect structure 426 to the second semiconductor devices 110(2). The power signals 135P can be transferred from third TSVs 122(3) that are coupled to second metal interconnects 130(2) and their interconnect vias 132(2), as power signal nodes 130P(2) (i.e., power and ground terminals or planes) in the PDN interconnect structure 426, to the second semiconductor devices 110(2). The power signals 135P are transferred from the third TSVs 122(3) in the PDN interconnect structure 426 to the second TSVs 122(2) in the semiconductor layer 108(2) coupled to the second semiconductor devices 110(2). For example, the IC package 400 may be coupled through the external interconnects 118 to a power source, such as a power management IC (PMIC) that is configured to supply power through power signals routed through the substrate 120 (e.g., as a package substrate).

As also shown in FIG. 4A, providing a separate PDN interconnect structure 426 in the IC 404 can also facilitate minimizing capacitance routing path lengths between a decoupling capacitor(s) 438 provided in the PDN interconnect structure 426, thereby also reducing loop inductance for improved power noise filtering. In this example, decoupling capacitors 438 are disposed in the PDN interconnect structure 426 and coupled to the second PDN 133(2) in the IC 404 provided therein by being coupled to second metal interconnects 130(2) that are interconnected by third TSVs 122(3) coupled to second TSVs 122(2) in the semiconductor layer 108(2) coupled to the second semiconductor devices 110(2) to power their operation. Providing a separate PDN interconnect structure 426 in the IC 404 may more easily facilitate the integration of the decoupling capacitors 438 into the PDN interconnect structure 426 and thus the IC 404, because there is reduced I/O signal routing in the PDN interconnect structure 426 as a result of providing the separate PDN interconnect structure 426 in the IC 404. This in turn provides shorter capacitance signal routing paths between the capacitor 438 and the second PDN 133(2) in the IC 404. This may avoid or reduce the need for a DSC or LSC that will have longer capacitance signal routing paths to the IC 404 due to the routing through the substrate 120.

In this example, the decoupling capacitors 438 are integrated into a separate silicon layer 442 in the separate PDN interconnect structure 426 as silicon capacitors (e.g., a DTC). The decoupling capacitors 438 interconnected to second metal interconnects 130(2) in the PDN interconnect structure 426 are coupled to the second PDN 133(2). The capacitor 438 could also be directly coupled to terminals of the second semiconductor devices 110(2) that are coupled to power signal nodes 130P(2) in the second metal Interconnects 130(2) to couple the capacitor 438 to the second PDN 133(2).

Also, as shown in FIG. 4B, the signal interconnect structure 124 and the PDN interconnect structure 426 may be fabricated separately as part of a second, separate wafer and coupled to or disposed adjacent to a second side 128(2) of the second semiconductor layer 108(2) opposite the first side 128(1) in the second, vertical direction (Z-axis direction). The combined second semiconductor layer 108(2) and signal interconnect structure 124 can be coupled to the separate PDN interconnect structure 426 through the metal bump layer 129 (e.g., from a wafer-on-wafer (WoW bonding process in fabrication) that includes the plurality of metal bumps 131 interconnected between exposed second TSVs 122(2) extending through the second semiconductor layer 108(2) in the second, vertical direction (Z-axis direction) and adjacent to the PDN interconnect structure 426, and exposed third TSVs 122(3) interconnected to second metal interconnects 130(2) in the PDN interconnect structure 426. Note that alternatively, the combined second semiconductor layer 108(2) and signal interconnect structure 124 could be coupled to the separate PDN interconnect structure 426 by a direct coupling or bonding exposed second TSVs 122(2) from the second semiconductor layer 108(2) to exposed third TSVs 122(3) interconnected to second metal interconnects 130(2) in the PDN interconnect structure 426.

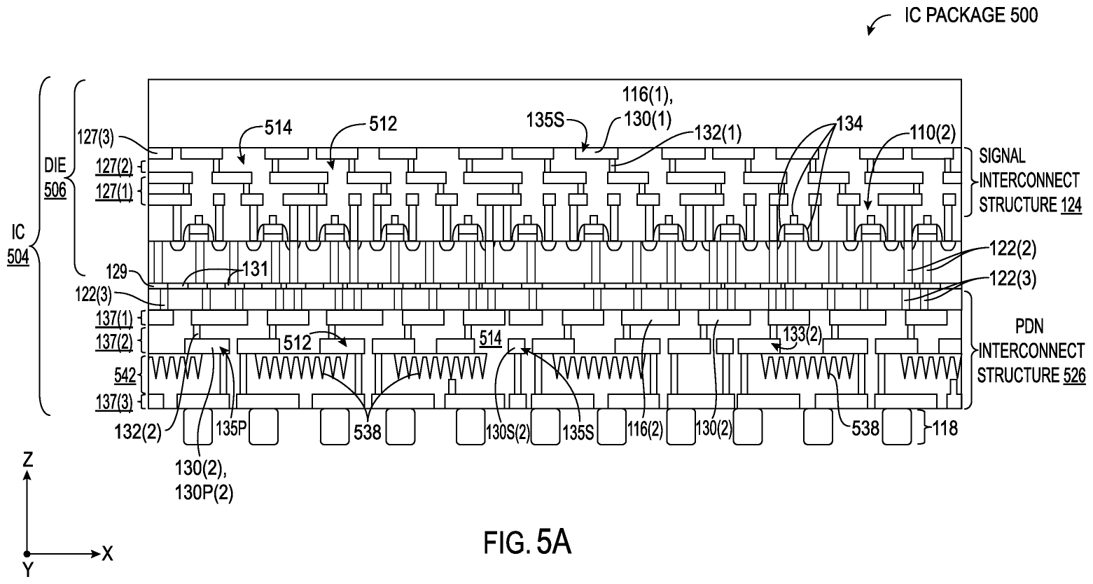

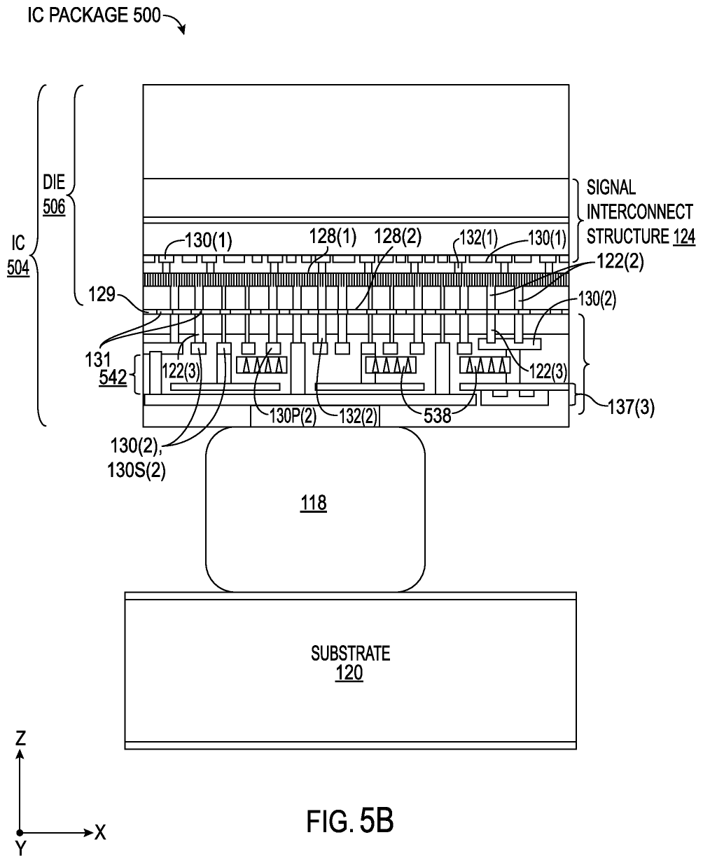

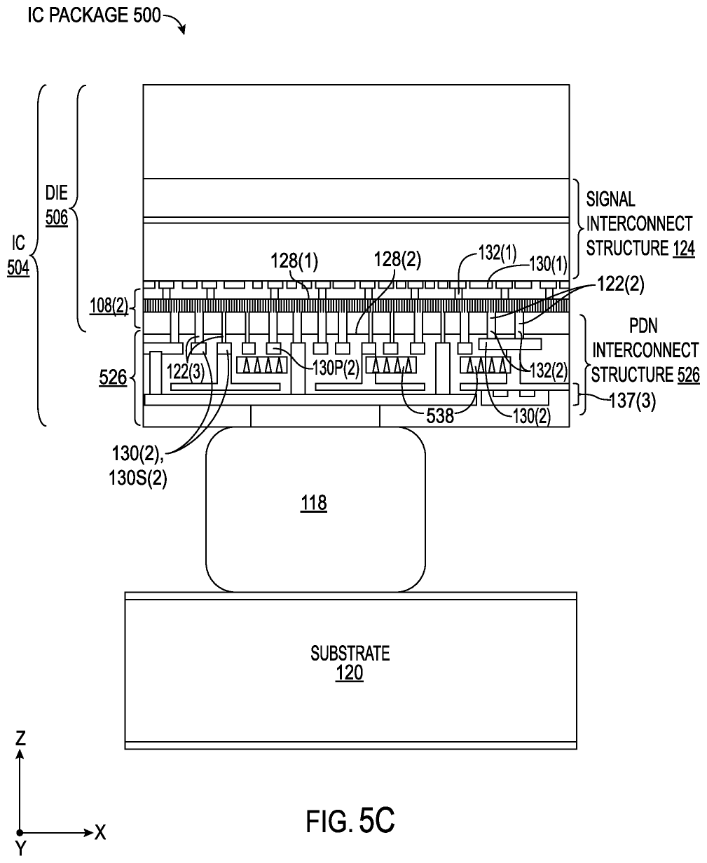

FIGS. 5A and 5B are a side view and close-up side view, respectively, of another exemplary IC package 500 that includes an IC 504 that includes a die 506 that also includes the separate signal interconnect structure 124. The IC 504 includes the die 506 with the signal interconnect structure 124, and the separate PDN interconnect structure 526 to reduce signal routing congestion and power signal routing path lengths in the IC 504 for improved performance of the die 506. The die 506 can be included as the second, upper die 106(2) in the 3DIC 102 in FIGS. 1A and 1B as a non-limiting example. Common elements between the die 506 in FIGS. 5A and 5B and the second, upper die 106(2) in FIGS. 1A and 1B are shown with common element numbers. As discussed below, in this example IC 504, the PDN interconnect structure 526 is similar to the PDN interconnect structures 126, 426 and the second, upper IC 104(2), in the 3DIC 102 in FIGS. 1A and 1B and the IC 404 in FIGS. 4A and 4B. However, the PDN interconnect structure 526 in the IC 504 includes a separate dielectric layer 542 (e.g., a silicon oxide layer) that has capacitors 538 disposed therein to provide the capacitors 538 as dielectric capacitors.

In this example, the die 506 is a semiconductor die by its inclusion of the semiconductor layer 108(2) and the signal interconnect structure 124. The PDN interconnect structure 526 does not include a semiconductor layer in which semiconductor devices are formed in this example. However, note that alternatively, the PDN interconnect structure 526 could be included as part of a die that also includes a semiconductor layer in which semiconductors devices are formed, and the signal interconnect structure 124 could be fabricated as not including a semiconductor layer.

With reference to FIG. 5A, the footprint of the IC 504 and its die 506 extends in first, horizontal directions (X-axis and Y-axis directions). The die 506 includes the second semiconductor layer 108(2) in which the second semiconductor devices 110(2) are formed like described for the 3DIC 102 in FIGS. 1A and 1B. The die 506 also has respective metal interconnect structures 512 (e.g., metal lines, metal traces) that have metallization layers 514 each having metal interconnects 116(1) to provide signal routing paths in the die 506 to their second semiconductor devices 110(2). As shown in FIG. 5A and the close-up side partial view of the IC 504 in FIG. 5B, the IC 504 includes the separate signal interconnect structure 124 and the PDN interconnect structure 526 to reduce signal routing congestion and power signal routing path lengths in the IC 504 for improved performance of the second semiconductor devices 110(2). The I/O and power signals 135S, 135P can be transferred from the second metal interconnects 130(2) in the PDN interconnect structure 526 to the second semiconductor devices 110(2). The power signals 135P can be transferred from third TSVs 122(3) that are coupled to second metal interconnects 130(2), as power signal nodes 130P(2) (i.e., power and ground terminals or planes) in the PDN interconnect structure 526, to be distributed to the second semiconductor devices 110(2) through interconnections between the second metal interconnects 130(2) interconnected by the second vias 132(2) and the second semiconductor devices 110(2). For example, the IC package 500 may be coupled through the external interconnects 118 to a power source, such as a PMIC that is configured to supply power through power signals routed through the substrate 120 (e.g., as a package substrate).

As also shown in FIG. 5A, providing a separate PDN interconnect structure 526 in the IC 504 can also facilitate minimizing capacitance routing path lengths between a decoupling capacitor 538 provided in the PDN interconnect structure 526, thereby also reducing loop inductance for improved power noise filtering. In this example, decoupling capacitors 538 are disposed in the PDN interconnect structure 526 and coupled to the second PDN 133(2) in the IC 504 provided therein by being coupled to a second metal interconnect(s) 130(2) that are interconnected by the second vias 132(2) and coupled to the second semiconductor devices 110(2) to power their operation. Providing a separate PDN interconnect structure 526 in the IC 504 may more easily facilitate the integration of the decoupling capacitors 538 into the PDN interconnect structure 526 and thus the IC 504, because there is reduced I/O signal routing in the PDN interconnect structure 526 as a result of providing the separate PDN interconnect structure 526 in the IC 504. This in turn provides shorter capacitance signal routing paths between the capacitor 538 and the second PDN 133(2) in the IC 504. This may avoid or reduce the need for a DSC or LSC that will have longer capacitance signal routing paths to the IC 504 due to the routing through the substrate 120.

In this example, the decoupling capacitors 538 are integrated into a separate dielectric layer 542 in the separate PDN interconnect structure 526 as silicon capacitors (e.g., integrated stack capacitors (ISCs)). The decoupling capacitors 538 are interconnected to second metal interconnects 130(2) in the PDN interconnect structure 526 to be coupled to the second PDN 133(2). The capacitors 538 could also be directly coupled to terminals of the second semiconductor devices 110(2) that are coupled to power signal nodes 130P(2) in the second metal interconnects 130(2) to couple the capacitor 538 to the second PDN 133(2).

Also, as shown in FIG. 5B, the signal interconnect structure 124 and the PDN interconnect structure 526 may be fabricated separately as part of a second, separate wafer and coupled to or disposed adjacent to a second side 128(2) of the second semiconductor layer 108(2) opposite the first side 128(1) in the second, vertical direction (Z-axis direction). The combined second semiconductor layer 108(2) and signal interconnect structure 124 can be coupled to the separate PDN interconnect structure 526 through the metal bump layer 129 (e.g., from a wafer-on-wafer (WoW) bonding process in fabrication) that includes the plurality of metal bumps 131. The metal bumps 131 are interconnected between exposed second TSVs 122(2) extending through the second semiconductor layer 108(2) in the second, vertical direction (Z-axis direction) and adjacent to the PDN interconnect structure 526, and exposed third TSVs 122(3) interconnected to second metal interconnects 130(2) in the PDN interconnect structure 526. Note that alternatively, as shown in FIG. 5C, the combined second semiconductor layer 108(2) and signal interconnect structure 124 could be coupled to the separate PDN interconnect structure 526 by a direct coupling or bonding exposed second TSVs 122(2) from the second semiconductor layer 108(2) to exposed third TSVs 122(3) interconnected to second metal interconnects 130(2) in the PDN interconnect structure 526.

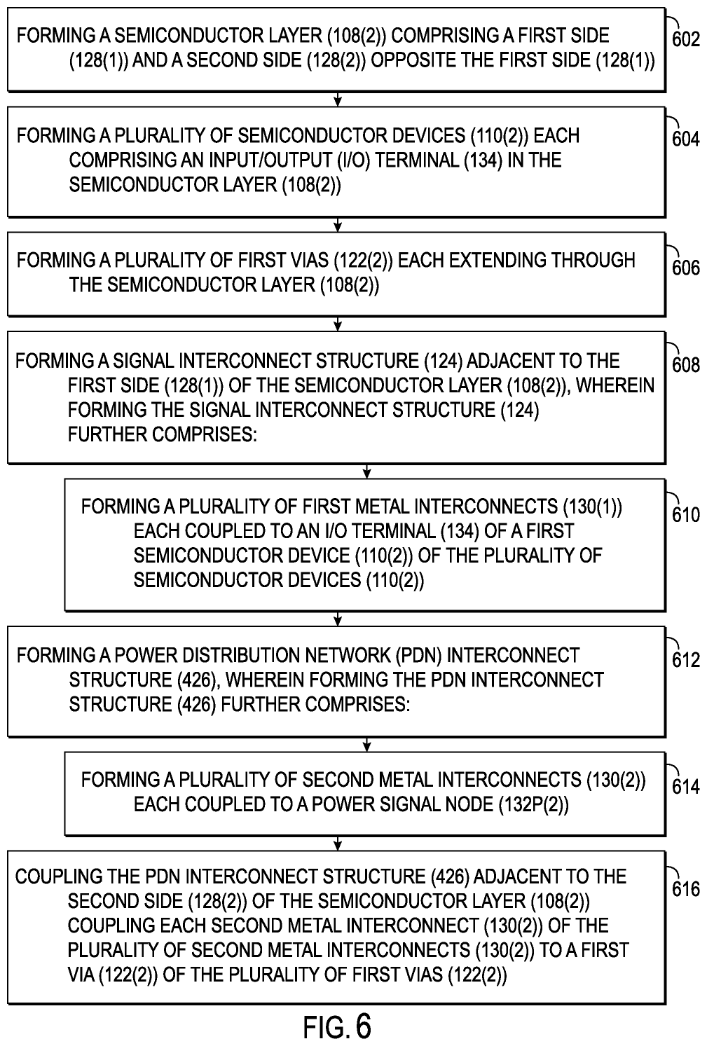

An IC that includes separate signal interconnect and PDN interconnect structures to reduce signal routing congestion and power signal routing path lengths for improved IC and die performance, and wherein decoupling capacitors can be integrated into the PDN interconnect structure of the IC to provide decoupling capacitance to the PDN in the IC, can be fabricated according to a fabrication process. In this regard, FIG. 6 is a flowchart illustrating an exemplary fabrication process 600 of fabricating an IC, including, but not limited to, the ICs 102, 404, 504 FIGS. 1A-1B, 4A-4B, and 5A-5C, that include separate signal interconnect and PDN interconnect structures to reduce signal routing congestion and power signal routing path lengths for improved IC and die performance, and wherein decoupling capacitors can be integrated into the PDN interconnect structure of the IC to provide decoupling capacitance to the PDN in the IC. The fabrication process 600 in FIG. 6 is discussed in reference to the IC 404 in FIGS. 4A-4B, but the fabrication process 600 is not limited to such.

In this regard, as shown in FIG. 6, the fabrication process 600 of fabricating the IC 404 can include forming a semiconductor layer 108(2) comprising a first side 128(1) and a second side 128(2) opposite the first side 128(1) (block 602 in FIG. 6). The fabrication process 600 can also include forming a plurality of semiconductor devices 110(2) each comprising an I/O terminal 134 in the semiconductor layer 108(2) (block 604 in FIG. 6). The fabrication process 600 can also include forming a plurality of first vias 122(2) each extending through the semiconductor layer 108(2) (block 606 in FIG. 6). The fabrication process 600 can also include forming a signal interconnect structure 124 adjacent to the first side 128(1) of the semiconductor layer 108(2) (block 608 in FIG. 6). Forming the signal interconnect structure 124 further comprises forming a plurality of first metal interconnects 130(1) each coupled to an I/O terminal 134 of a first semiconductor device 110(2) of the plurality of semiconductor devices 110(2) (block 610 in FIG. 6). The fabrication process 600 can also include forming the PDN interconnect structure 426 (block 612 in FIG. 6). Forming the PDN interconnect structure 426 further comprises forming a plurality of second metal interconnects 130(2) each coupled to a power signal node 130P(2) (block 614 in FIG. 6). The fabrication process 600 can also include coupling the PDN interconnect structure 426 adjacent to the second side 128(2) of the semiconductor layer 108(2) coupling each second metal interconnect 130(2) of the plurality of second metal interconnects 130(2) to a first via 122(2) of the plurality of vias 122(2) (block 616 in FIG. 6).

An IC that includes separate signal interconnect and PDN interconnect structures to reduce signal routing congestion and power signal routing path lengths for improved IC and die performance, and wherein decoupling capacitors can be integrated into the PDN interconnect structure of the IC to provide decoupling capacitance to the PDN in the IC, can be fabricated according to a fabrication process. In this regard, FIG. 6 is a flowchart illustrating an exemplary fabrication process 600 of fabricating an IC, including, but not limited to, the ICs 102, 404, 504 in FIGS. 1A-1B, 4A-5C that can be fabricated in other fabrication processes.

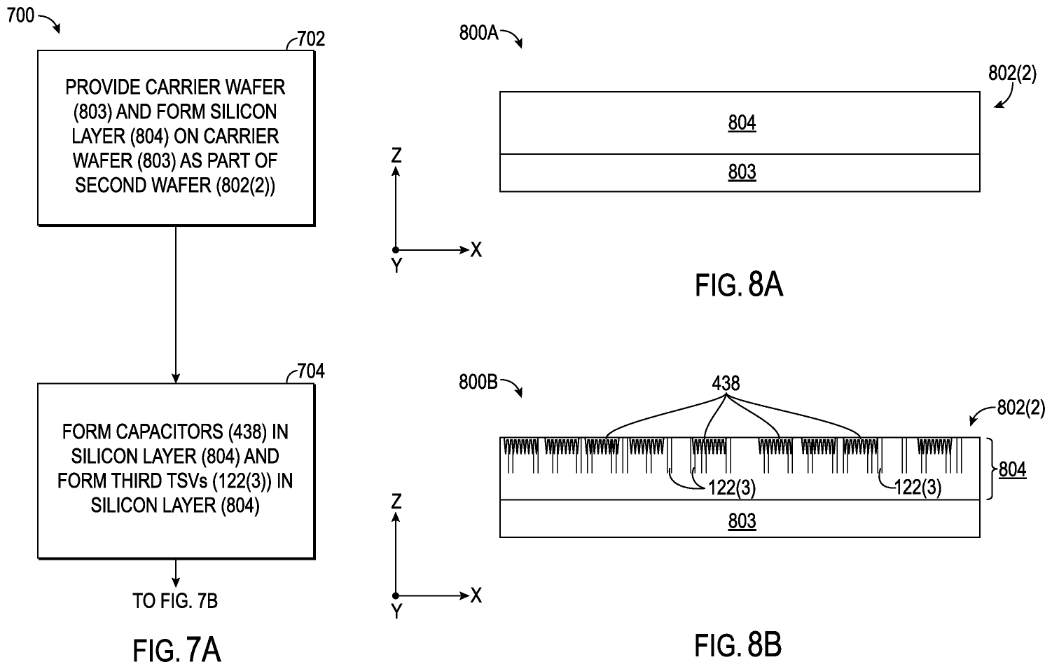

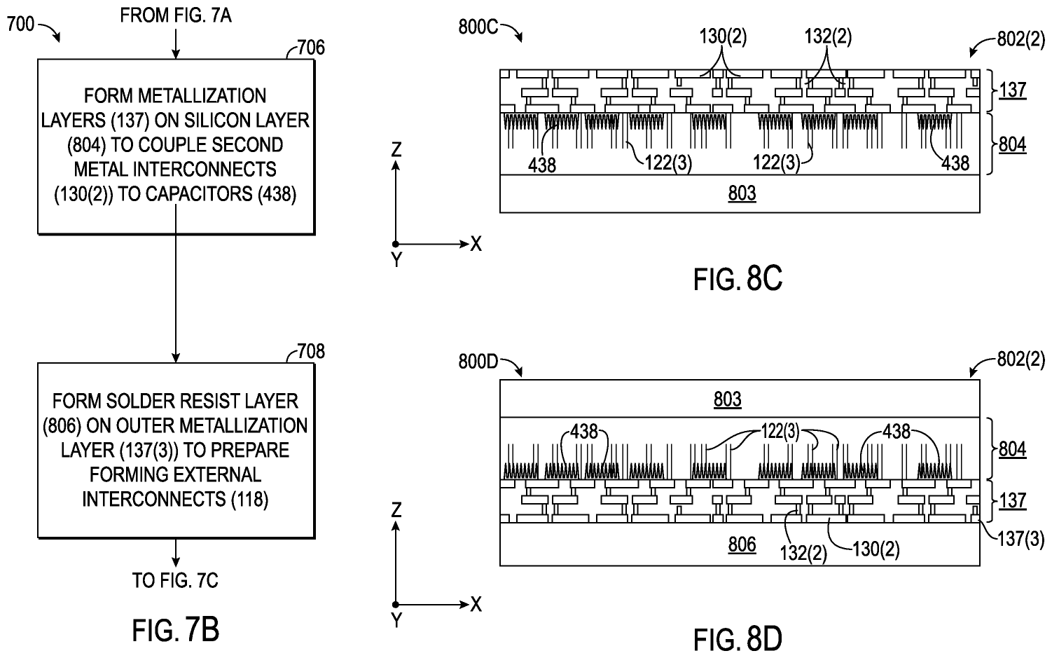

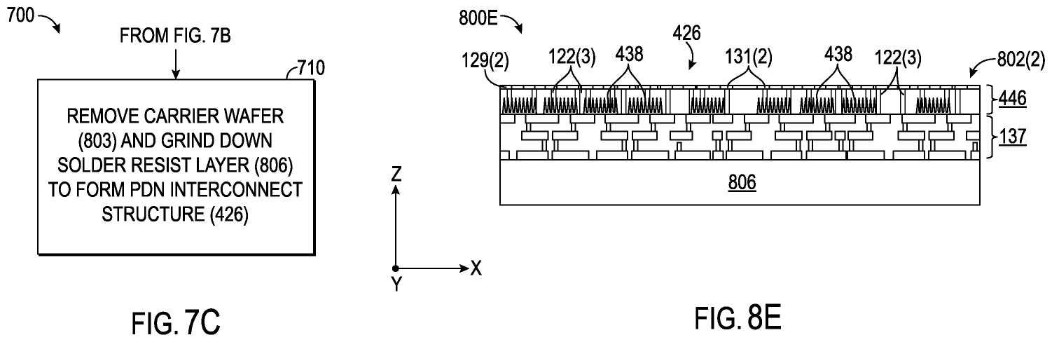

For example, FIGS. 7A-7C is a flowchart illustrating a fabrication process 700 of fabricating a second wafer 802(2) that includes the PDN interconnect structure 426 as part of the IC 404 in FIGS. 4A and 4B. As discussed later, the second wafer 802(2) with the PDN interconnect structure 426 can be coupled to a first wafer that includes the second semiconductor layer 108(2) and signal interconnect structure 124 to form the die 406 as part of a WoW bonding process. As discussed above, fabricating the PDN interconnect structure 426 and the second semiconductor layer 108(2) and signal interconnect structure 124 as separate wafers has the advantage of using die fabrication processes to form the IC 404 with its two separate PDN and signal interconnect structures 426, 124. FIGS. 8A-8E are exemplary fabrication stages 800A-800E during fabrication of the PDN interconnect structure 426 according to the exemplary fabrication process 700 in FIGS. 7A-7C. The fabrication process 700 in FIGS. 7A-7C is discussed below with reference to the exemplary IC 404 FIGS. 4A and 4B, but such is not limiting.

In this regard, as shown in the exemplary fabrication stage 800A in FIG. 8A, a first step in the fabrication process 700 of fabricating the second wafer 802(2) that includes the PDN interconnect structure 426 is to provide a carrier wafer 803 and to form a silicon layer 804 on the carrier wafer 803 (block 702 in FIG. 7A). This is to prepare the silicon layer 804 to be processed to form the capacitors 438 in the silicon layer 804 that will be become the silicon layer 442 in the PDN interconnect structure 426, wherein the capacitors 438 will be coupled to the second metal interconnects 130(2) that are part of the second PDN 133(2) to provide decoupling capacitance in the IC 404. Then, as shown in exemplary fabrication stage 800B in FIG. 8B, a next step in the fabrication process 700 of fabricating the second wafer 802(2) that includes the PDN interconnect structure 426 is to form the capacitors 438 in the silicon layer 804, and form the third TSVs 122(3) in the silicon layer 804 (block 704 in FIG. 7A). This is to provide signal routing paths between the PDN interconnect structure 426 and the capacitors 438 and an eventual second semiconductor layer 108(2) and signal interconnect structure 124 that coupled to the PDN interconnect structure 426.

Then, as shown in exemplary fabrication stage 800C in FIG. 8C, a next step in the fabrication process 700 of fabricating the second wafer 802(2) that includes the PDN interconnect structure 426 is to form the metallization layers 137 on the silicon layer 804, with certain metal interconnects 130(2) in the metallization layers 137 coupled to capacitors 438 (block 706 in FIG. 7B). The metallization layers 137 may be formed using a BEOL process that is normally used to form metallization layers in a die. Then, as shown in exemplary fabrication stage 800D in FIG. 8D, a next step in the fabrication process 700 of fabricating the second wafer 802(2) that includes the PDN interconnect structure 426 is to dispose a solder resist layer 806 on the metallization layers 137 to prepare the openings in the outer metallization layer 137(3) for forming the external interconnects 118 (block 708 in FIG. 7B). Then, as shown in exemplary fabrication stage 800E in FIG. 8E, a next step in the fabrication process 700 of fabricating the second wafer 802(2) that includes the PDN interconnect structure 426 is to remove the carrier wafer 803 and then grind down the solder resist layer 806 to form the PDN interconnect structure 426 and prepare the metallization layers 137 for bumping to form the external interconnects 118 to be formed in contact with second metal interconnects 130(2) in the outer metallization layer 137(3) (block 710 in FIG. 7C). A second metal bump layer 129(2) with second metal bumps 131(2) is also formed on the silicon layer 446 to prepare the PDN interconnect structure 426 to be bonded to another wafer that will have the second semiconductor layer 108(2) and signal interconnect structure 124 formed as part of a separate wafer, as part of a WoW bonding process.

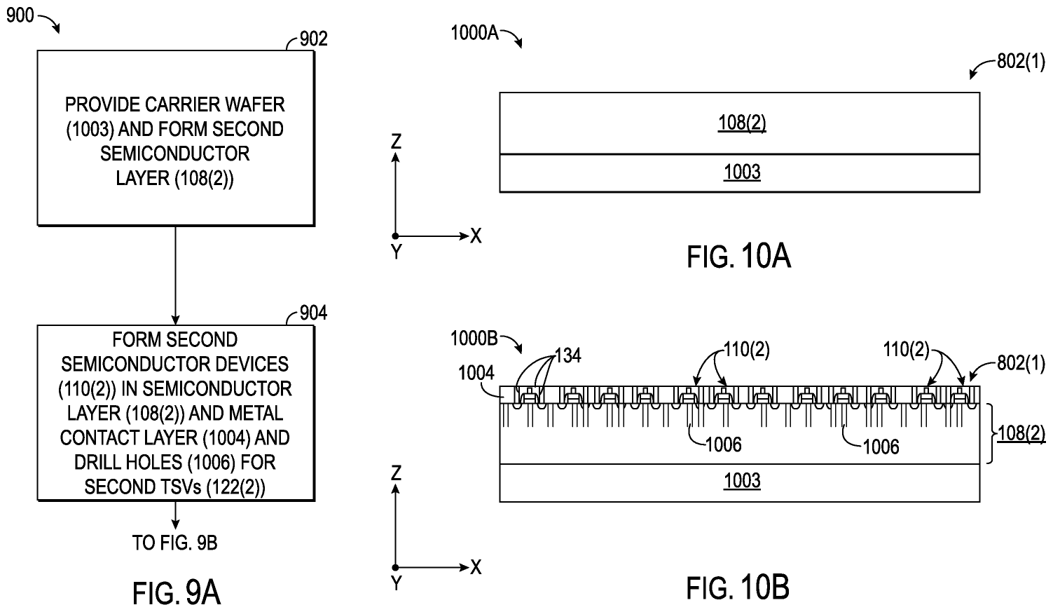

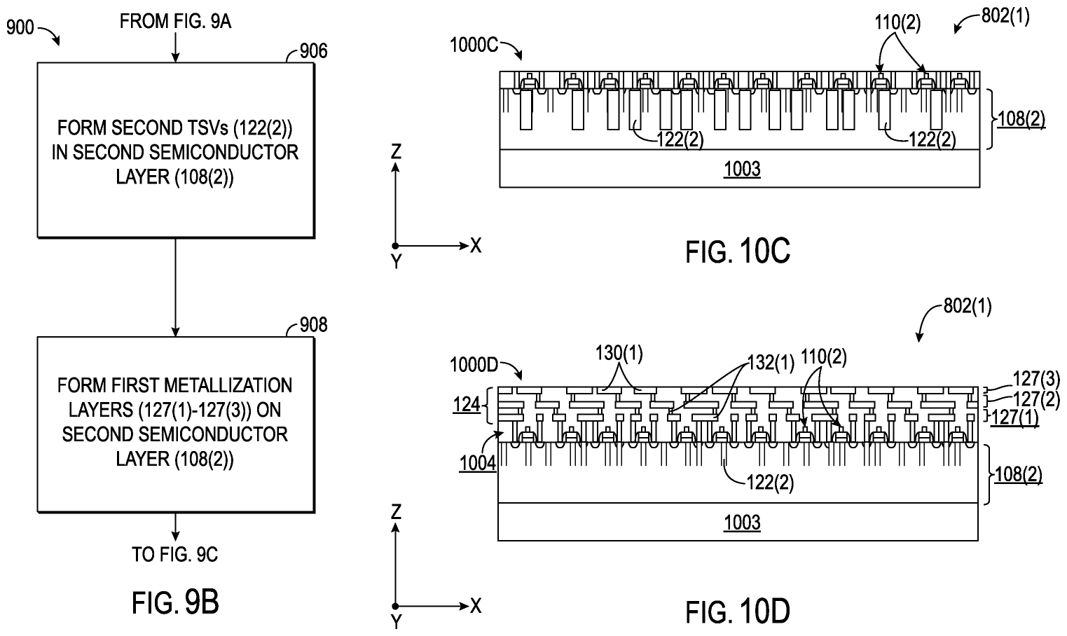

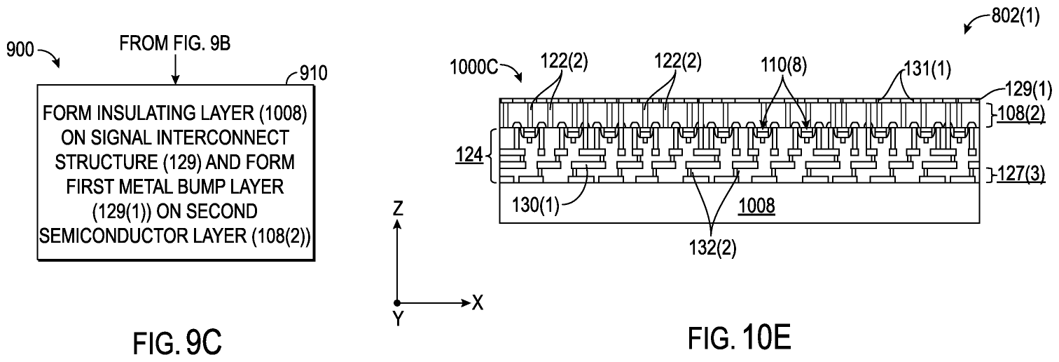

FIGS. 9A-9C is a flowchart illustrating an exemplary fabrication process 900 of separately fabricating the second semiconductor layer 108(2) and signal interconnect structure 124 as part of a separate first wafer 802(1) that will be coupled to the second wafer 802(2) with the PDN interconnect structure 426 to form a combined wafer that can then be diced to form ICs like the IC 404 in FIGS. 4A and 4B. FIGS. 10A-10E are exemplary fabrication stages 1000A-1000E during fabrication of the first wafer 802(1) that will include the second semiconductor layer 108(2) and signal interconnect structure 124 that can be coupled to the second wafer 802(2) in FIG. 8E to form a combined wafer that can be diced into ICs like the IC 404 in FIGS. 4A and 4B according to the exemplary fabrication process 900 in FIGS. 9A-9C. The fabrication process 900 in FIGS. 9A-9C is discussed below with reference to the exemplary die 406 in the IC 404 in FIGS. 4A and 4B, but such is not limiting.

In this regard, as shown in exemplary fabrication stage 1000A in FIG. 10A, a first step in the fabrication process 900 of fabricating the first wafer 802(1) that includes the second semiconductor layer 108(2) and the signal interconnect structure 124 is to provide a carrier wafer 1003 and to form the second semiconductor layer 108(2) that is subjected to diffusion to prepare for the formation of the second semiconductor devices 110(2) therein (block 902 in FIG. 9A). Then, as shown in exemplary fabrication stage 1000B in FIG. 10B, a next step in the fabrication process 900 of fabricating the first wafer 802(1) includes forming the second semiconductor devices 110(2) in the second semiconductor layer 108(2) and drill holes 1006 drilled into the second semiconductor layer 108(2) to form the second TSVs 122(2) (block 904 in FIG. 9A). Part of forming the second semiconductor devices 110(2) is to form a metal contact layer 1004 that includes gates and metal contacts for the second semiconductor devices 110(2), any of which can be I/O terminals 134.

Then, as shown in exemplary fabrication stage 1000C in FIG. 10C, a next step in the fabrication process 900 of fabricating the first wafer 802(1) that includes the second semiconductor layer 108(2) and the signal interconnect structure 124 is to form the second TSVs 122(2) in the second semiconductor layer 108(2) by depositing metal into the drill holes 1006 (block 906 in FIG. 9B). The second TSVs 122(2) will be coupled to the second semiconductor devices 110(2) (block 906 in FIG. 9B). The second TSVs 122(2) will eventually be coupled to the PDN interconnect structure 426 in the second wafer 802(2) in FIG. 8E to provide signal routing paths between the PDN interconnect structure 426 and the second semiconductor layer 108(2) and its second semiconductor devices 110(2) and signal interconnect structure 124. Then, as shown in exemplary fabrication stage 1000D in FIG. 10D, a next step in the fabrication process 900 of fabricating the first wafer 802(1) is to form first metallization layers 127(1)-127(3) and their first metal interconnects 130(1) and the first vias 132(1) that form the signal interconnect structure 124 on the metal contact layer 1004 and the second semiconductor layer 108(2). Certain first metal interconnects 130(1) are coupled to the second TSVs 122(2) and the second semiconductor devices 110(2) to provide I/O signal 135S routing to the second semiconductor devices 110(2) and eventually the PDN interconnect structure 426 when its second wafer 802(2) is coupled to the first wafer 802(1) (block 908 in FIG. 9B). The first metallization layers 127(1)-127(3) may be formed as part of a BEOL fabrication process.

Then, as shown in exemplary fabrication stage 1000E in FIG. 10E, a next step in the fabrication process 900 of fabricating the first wafer 802(1) that includes the second semiconductor layer 108(2) and the signal interconnect structure 124 is to remove the carrier wafer 1003 and form an insulating layer 1008 on an outer metallization layer 127(3) of the signal interconnect structure 124 to protect the signal interconnect structure 124 (block 910 in FIG. 9C). A first metal bump layer 129(1) with first metal bumps 131(1) is also formed on the second semiconductor layer 108(2) with the first metal bumps 131(1) coupled to the second TSVs 122(2) to prepare the first wafer 802(1) to be bonded to the second wafer 802(2) in FIG. 8E as part of a WoW bonding process.

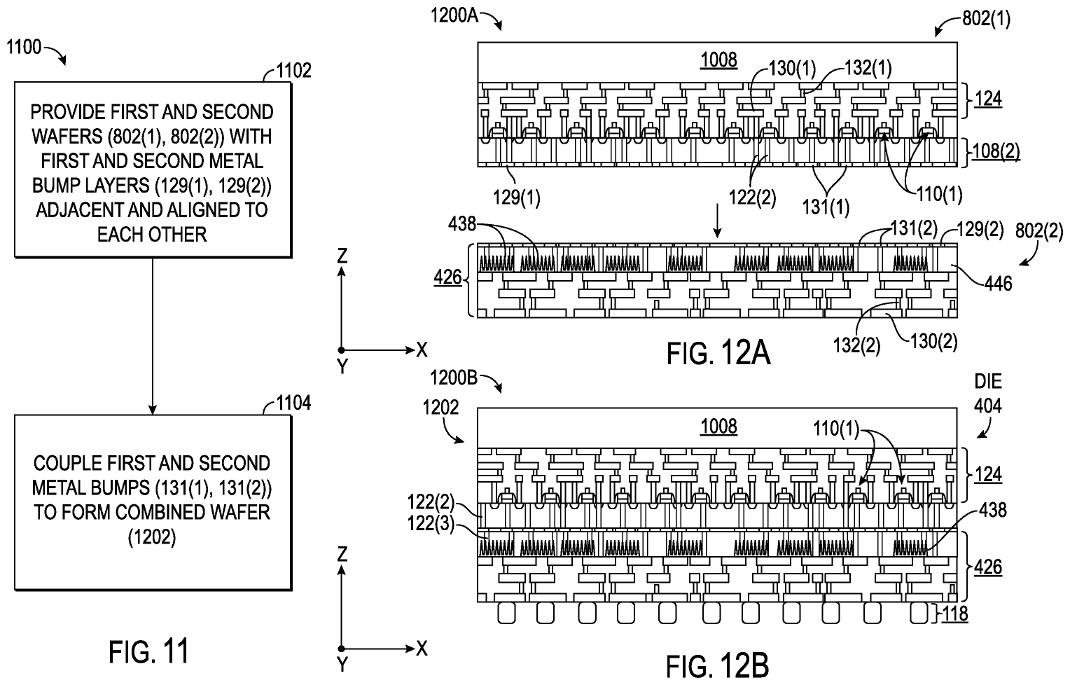

FIG. 11 is a flowchart illustrating an exemplary fabrication process 1100 of coupling the separately fabricated second wafer 802(2) with the PDN interconnect structure 426 in FIG. 8E to the first wafer 802(1) with the second semiconductor layer 108(2) and signal interconnect structure 124 in FIG. 10E to form a combined wafer 1202 that can be diced into separate ICs like the IC 404 in FIGS. 4A and 4B. FIGS. 12A and 12B are exemplary fabrication stages 1200A-1200B during coupling the separately fabricated second wafer 802(2) with the PDN interconnect structure 426 in FIG. 8E to the first wafer 802(1) with the second semiconductor layer 108(2) and signal interconnect structure 124 in FIG. 10E to form a combined wafer 1202 that can be diced into separate ICs like the IC 404 in FIGS. 4A and 4B, and according to the exemplary process in FIG. 11.

In this regard, as shown in exemplary fabrication stage 1200A in FIG. 12A, a first step in the fabrication process 1100 of fabricating the IC 404 in FIGS. 4A and 4B is to provide the first wafer 802(1) and the second wafer 802(2) and to align the first and second wafers 802(1), 802(2) so that their respective metal bump layers 129(1), 129(2) are adjacent to each other and aligned for coupling (block 1102 in FIG. 11). Then, as shown in exemplary fabrication stage 1200B in FIG. 12B, a next step in the fabrication process 1100 of fabricating the IC 404 in FIGS. 4A and 4B is to couple the first and second metal bumps 131(1), 131(2) of the respective first and second wafers 802(1), 802(2) to couple the first wafer 802(1) to the second wafer 802(1) to provide a combined wafer 1202 (block 1104 in FIG. 11). This provides an electrical coupling for signal routing paths between the PDN interconnect structure 426 and the second semiconductor layer 108(2) and signal interconnect structure 124. The combined wafer 1202 can then be diced to form multiple ICs like the IC 404 in FIGS. 4A and 4B.

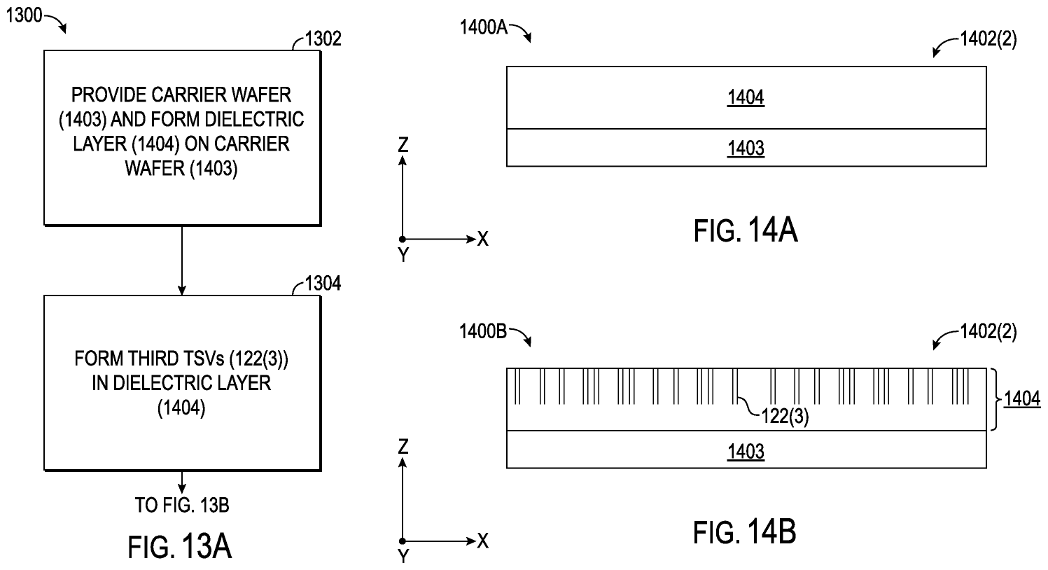

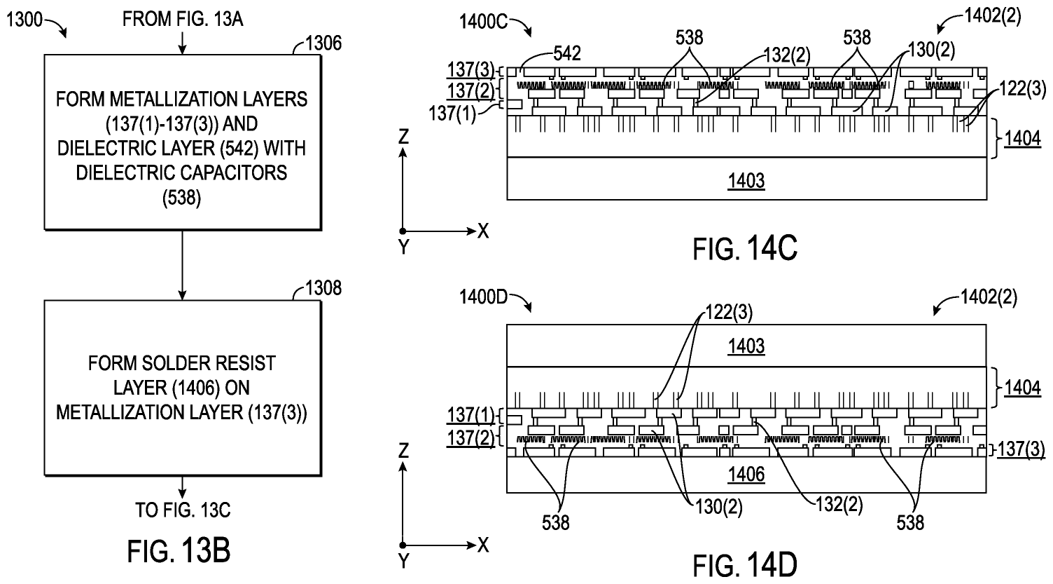

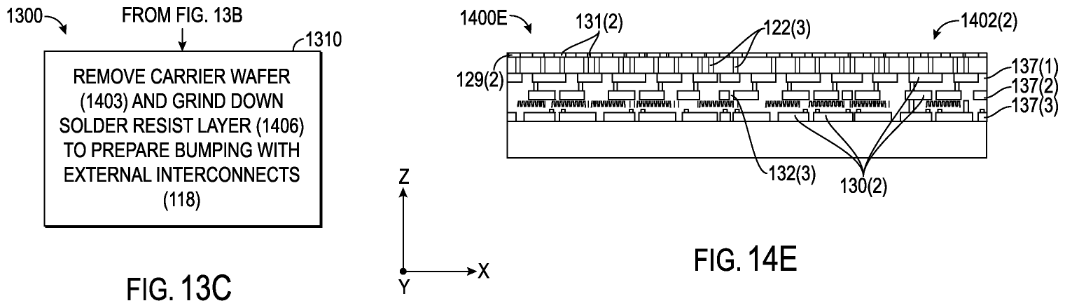

FIGS. 13A-13C is a flowchart illustrating a fabrication process 1300 of fabricating a second wafer 1402(2) that includes the PDN interconnect structure 526 as part of the IC 504 in FIGS. 5A and 5B. As discussed later, the second wafer 1402(2) with the PDN interconnect structure 526 can be coupled to the first wafer 802(1) in FIG. 10E that includes the second semiconductor layer 108(2) and signal interconnect structure 124 in FIGS. 5A-5B and 10E and to form the die 506 as part of a WoW bonding process. As discussed above, fabricating the PDN interconnect structure 526 and the second semiconductor layer 108(2) and signal interconnect structure 124 as separate wafers has the advantage of using die fabrication processes to form the IC 504 with its two separate PDN and signal interconnect structures 526, 124. FIGS. 14A-14E are exemplary fabrication stages 1400A-1400E during fabrication of the PDN interconnect structure 526 according to the exemplary fabrication process 1300 in FIGS. 13A-13C. The fabrication process 1300 in FIGS. 13A-13C is discussed below with reference to the exemplary IC 504 in FIGS. 5A and 5B, but such is not limiting.

In this regard, as shown in the exemplary fabrication stage 1400A in FIG. 14A, a first step in the fabrication process 1300 of fabricating the second wafer 1402(2) that includes the PDN interconnect structure 526 is to provide a carrier wafer 1403 and to form a dielectric layer 1404 on the carrier wafer 1403 (block 1302 in FIG. 13A). This is to prepare the dielectric layer 1404 to be processed to form the third TSVs 122(3) in the PDN interconnect structure 526. Then, as shown in exemplary fabrication stage 1400B in FIG. 14B, a next step in the fabrication process 1300 of fabricating the second wafer 1404(2) that includes the PDN interconnect structure 526 is to form the third TSVs 122(3) in the dielectric layer 1404 (block 1304 in FIG. 13A). This is to provide signal routing paths between the PDN interconnect structure 526 and the capacitors 538 and metal interconnects 130(2) that will be formed in added metallization layers 137(1)-137(3) and an eventual second semiconductor layer 108(2) and signal interconnect structure 124 coupled to the PDN interconnect structure 526.

Then, as shown in exemplary fabrication stage 1400C in FIG. 14C, a next step in the fabrication process 1300 of fabricating the second wafer 1402(2) that includes the PDN interconnect structure 526 is to form the metallization layers 137(1)-137(3) on the dielectric layer 1404, with certain metal interconnects 130(2) in the metallization layers 137(1)-137(3) and to form a dielectric layer 542 with dielectric capacitors 538 formed therein coupled to the metal interconnects 130(2) to provide a decoupling capacitance (block 1306 in FIG. 13B). The metallization layers 137(1)-137(3) may be formed using a BEOL process that is normally used to form metallization layers in a die. Then, as shown in exemplary fabrication stage 1400D in FIG. 14D, a next step in the fabrication process 1300 of fabricating the second wafer 1402(2) that includes the PDN interconnect structure 526 is to dispose a solder resist layer 1406 on the dielectric layer 542 to prepare the openings in an outer metallization layer 137(3) for forming the external interconnects 118 (block 1308 in FIG. 13B).

Then, as shown in exemplary fabrication stage 1400E in FIG. 14E, a next step in the fabrication process 1300 of fabricating the second wafer 1402(2) that includes the PDN interconnect structure 526 is to remove the carrier wafer 1403 and then grind down the solder resist layer 1406 to form the PDN interconnect structure 526 and prepare the outer metallization layer 137(3) for bumping to form the external interconnects 118 to be formed in contact with second metal interconnects 130(2) in the outer metallization layer 137(3) (block 1310 in FIG. 13C). A second metal bump layer 129(2) with second metal bumps 131(2) is also formed on the dielectric layer 546 to prepare the PDN interconnect structure 526 to be bonded to another the first wafer 802(1) in FIG. 10E that will have the second semiconductor layer 108(2) and signal interconnect structure 124 formed as part of a separate wafer, as part of a WoW bonding process.

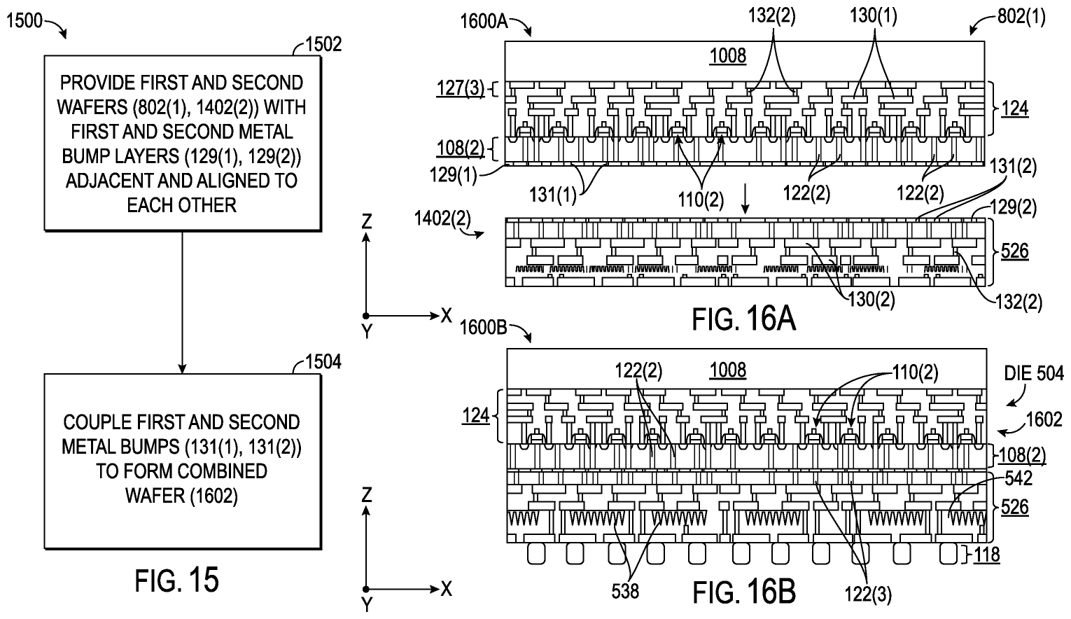

FIG. 15 is a flowchart illustrating an exemplary process 1500 of coupling the separately fabricated second wafer 1402(2) with the PDN interconnect structure 526 in FIG. 14E to the first wafer 802(1) with the second semiconductor layer 108(2) and signal interconnect structure 124 in FIG. 10E to form a combined wafer 1602 that can be diced into separate ICs like the IC 504 in FIGS. 5A and 5B. FIGS. 16A and 16B are exemplary fabrication stages 1600A-1600B during coupling the separately fabricated second wafer 1402(2) with the PDN interconnect structure 526 in FIG. 14E to the first wafer 802(1) with the second semiconductor layer 108(2) and signal interconnect structure 124 in FIG. 10E to form a combined wafer 1602 that can be diced into separate ICs like the IC 504 in FIGS. 5A and 5B, according to the exemplary process in FIG. 11.

In this regard, as shown in exemplary fabrication stage 1600A in FIG. 16A, a first step in the fabrication process 1500 of fabricating the IC 504 in FIGS. 5A and 5B is to provide the first wafer 802(1) in FIG. 10E and the second wafer 1402(2) in FIG. 14E and to align the first and second wafers 802(1), 1402(2) so that their respective metal bump layers 129(1), 129(2) are adjacent to each other and aligned for coupling (block 1502 in FIG. 15). Then, as shown in exemplary fabrication stage 1600B in FIG. 16B, a next step in the fabrication process 1500 of fabricating the IC 504 in FIGS. 5A and 5B is to couple the first and second metal bumps 131(1), 132(2) of the respective first and second wafers 802(1), 1402(2) to couple the first wafer 802(1) to the second wafer 1402(1) to provide a combined wafer 1602 (block 1504 in FIG. 15). This provides an electrical coupling for signal routing paths between the PDN interconnect structure 526 and the second semiconductor layer 108(2) and signal interconnect structure 124. The combined wafer 1602 can then be diced to form multiple ICs like the IC 504 in FIGS. 5A and 5B.

It should be understood that the terms “first,” “second,” “third,” etc., where used herein, are relative terms and are not meant to limit or imply a strict orientation. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

ICs that include separate signal interconnect and PDN interconnect structures to reduce signal routing congestion and power signal routing path lengths for improved IC and die performance, and wherein decoupling capacitors can be integrated into the PDN interconnect structure of the IC to provide decoupling capacitance to the PDN in the IC, including, but not limited to, the ICs 102, 404, 504 FIGS. 1A-1B, 4A-5C, 12B, and 16B, and that can be fabricated according to a fabrication process, including, but not limited to, the exemplary fabrication processes 600, 700, 900, 1100, 1300, 1500 in FIGS. 6, 7A-7C, 9A-9C, 11, 13A-13C, and 15, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

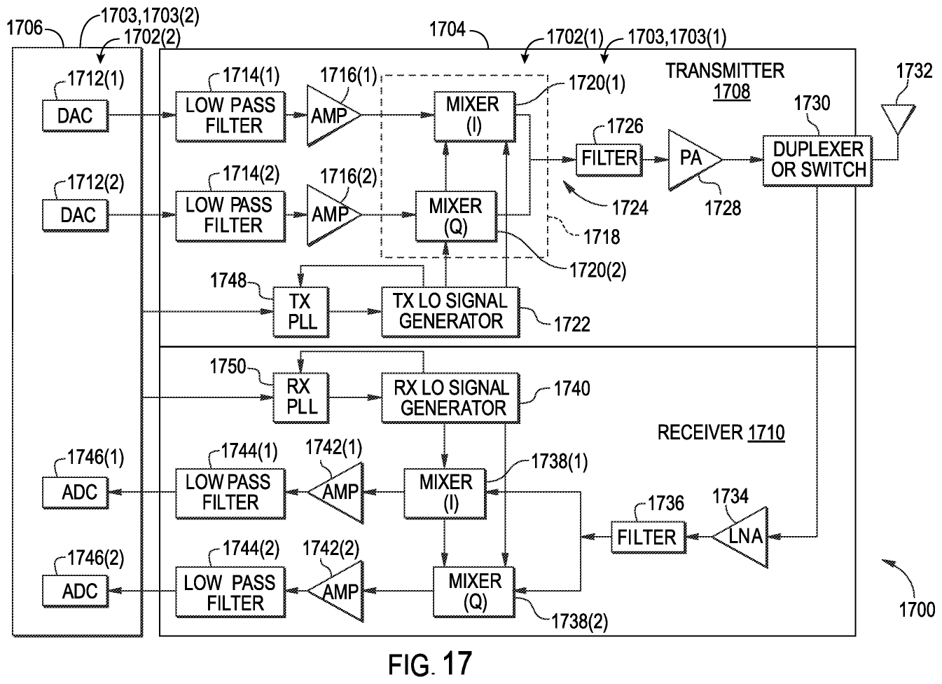

In this regard, FIG. 17 illustrates an exemplary wireless communications device 1700 that includes one or more IC packages 1702(1), 1702(2) that include one or more ICs 1703, 1703(1) 1703(2), including, but not limited to, the ICs 102, 404, 504 in FIGS. 1A-1B, 4A-5C, 12B, and 16B, that include separate signal interconnect and PDN interconnect structures to reduce signal routing congestion and power signal routing path lengths for improved IC and die performance, and wherein decoupling capacitors can be integrated into the PDN interconnect structure of the IC to provide decoupling capacitance to the PDN in the IC, and that can be fabricated according to a fabrication process, including, but not limited to, the exemplary fabrication processes 600, 700, 900, 1100, 1300, 1500 in FIGS. 6, 7A-7C, 9A-9C, 11, 13A-13C, and 15, and according to any aspects disclosed herein.

The wireless communications device 1700 may include or be provided in any of the above-referenced devices, as examples. As shown in FIG. 17, the wireless communications device 1700 includes a transceiver 1704 and a data processor 1706. The data processor 1706 may include a memory to store data and program codes. The transceiver 1704 includes a transmitter 1708 and a receiver 1710 that support bi-directional communications. In general, the wireless communications device 1700 may include any number of transmitters 1708 and/or receivers 1710 for any number of communication systems and frequency bands. All or a portion of the transceiver 1704 may be implemented on one or more analog ICs, RF ICs (RFICs), mixed-signal ICs, etc.

The transmitter 1708 or the receiver 1710 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1710. In the direct-conversion architecture, a signal is frequency-converted between RF and baseband in one stage. The super-heterodyne and direct-conversion architectures may use different circuit blocks and/or have different requirements. In the wireless communications device 1700 in FIG. 17, the transmitter 1708 and the receiver 1710 are implemented with the direct-conversion architecture.

In the transmit path, the data processor 1706 processes data to be transmitted and provides I and Q analog output signals to the transmitter 1708. In the exemplary wireless communications device 1700, the data processor 1706 includes digital-to-analog converters (DACs) 1712(1), 1712(2) for converting digital signals generated by the data processor 1706 into the I and Q analog output signals, e.g., I and Q output currents, for further processing.

Within the transmitter 1708, lowpass filters 1714(1), 1714(2) filter the I and Q analog output signals, respectively, to remove undesired signals caused by the prior digital-to-analog conversion. Amplifiers (AMPs) 1716(1), 1716(2) amplify the signals from the lowpass filters 1714(1), 1714(2), respectively, and provide I and Q baseband signals. An upconverter 1718 upconverts the I and Q baseband signals with I and Q transmit (TX) local oscillator (LO) signals through mixers 1720(1), 1720(2) from a TX LO signal generator 1722 to provide an upconverted signal 1724. A filter 1726 filters the upconverted signal 1724 to remove undesired signals caused by the frequency upconversion as well as noise in a receive frequency band. A power amplifier (PA) 1728 amplifies the upconverted signal 1724 from the filter 1726 to obtain the desired output power level and provides a transmit RF signal. The transmit RF signal is routed through a duplexer or switch 1730 and transmitted via an antenna 1732.

In the receive path, the antenna 1732 receives signals transmitted by base stations and provides a received RF signal, which is routed through the duplexer or switch 1730 and provided to a low noise amplifier (LNA) 1734. The duplexer or switch 1730 is designed to operate with a specific receive (RX)-to-TX duplexer frequency separation, such that RX signals are isolated from TX signals. The received RF signal is amplified by the LNA 1734 and filtered by a filter 1736 to obtain a desired RF input signal. Downconversion mixers 1738(1), 1738(2) mix the output of the filter 1736 with I and Q RX LO signals (i.e., LO_I and LO_Q) from an RX LO signal generator 1740 to generate I and Q baseband signals. The I and Q baseband signals are amplified by AMPs 1742(1), 1742(2) and further filtered by lowpass filters 1744(1), 1744(2) to obtain I and Q analog input signals, which are provided to the data processor 1706. In this example, the data processor 1706 includes analog-to-digital converters (ADCs) 1746(1), 1746(2) for converting the analog input signals into digital signals to be further processed by the data processor 1706.

In the wireless communications device 1700 of FIG. 17, the TX LO signal generator 1722 generates the I and Q TX LO signals used for frequency upconversion, while the RX LO signal generator 1740 generates the I and Q RX LO signals used for frequency downconversion. Each LO signal is a periodic signal with a particular fundamental frequency. A TX phase-locked loop (PLL) circuit 1748 receives timing information from the data processor 1706 and generates a control signal used to adjust the frequency and/or phase of the TX LO signals from the TX LO signal generator 1722. Similarly, an RX PLL circuit 1750 receives timing information from the data processor 1706 and generates a control signal used to adjust the frequency and/or phase of the RX LO signals from the RX LO signal generator 1740.

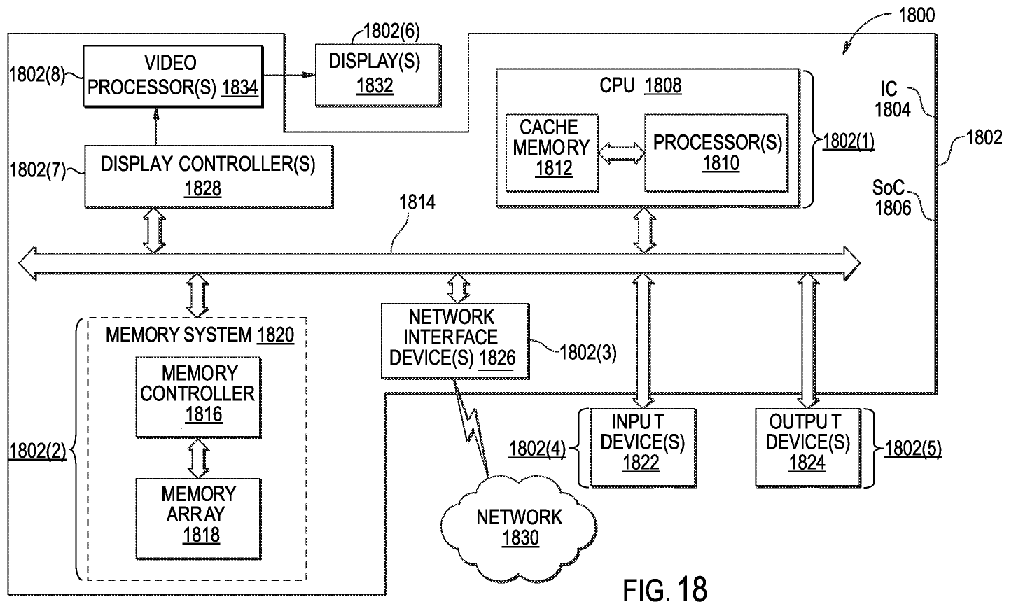

FIG. 18 illustrates an example of a processor-based system 1800 that includes one or more IC packages 1802, 1802(1)-1802(8) that include one or more ICs, including, but not limited to, the ICs 102, 404, 504 in FIGS. 1A-1B, 4A-5C, 12B, and 16B, that include separate signal interconnect and PDN interconnect structures to reduce signal routing congestion and power signal routing path lengths for improved IC and die performance, and wherein decoupling capacitors can be integrated into the PDN interconnect structure of the IC to provide decoupling capacitance to the PDN in the IC, and that can be fabricated according to a fabrication process, including, but not limited to, the exemplary fabrication processes 600, 700, 900, 1100, 1300, 1500 in FIGS. 6, 7A-7C, 9A-9C, 11, 13A-13C, and 15, and according to any aspects disclosed herein.

In this example, the processor-based system 1800 may include a capacitor package(s) 1804 that is included in an IC package 1802, such as a system-on-a-chip (SoC) 1806. The processor-based system 1800 includes a CPU 1808 that includes one or more processors 1810, which may also be referred to as CPU cores or processor cores. The CPU 1808 can be provided in an IC package 1802(1) that includes a package substrate with the embedded capacitor package 1804(1). The CPU 1808 may have cache memory 1812 coupled to the CPU 1808 for rapid access to temporarily stored data. The CPU 1808 is coupled to a system bus 1814 and can intercouple master and slave devices included in the processor-based system 1800. As is well known, the CPU 1808 communicates with these other devices by exchanging address, control, and data information over the system bus 1814. For example, the CPU 1808 can communicate bus transaction requests to a memory controller 1816 as an example of a slave device. Although not illustrated in FIG. 18, multiple system buses 1814 could be provided, wherein each system bus 1814 constitutes a different fabric.

Other master and slave devices can be connected to the system bus 1814. As illustrated in FIG. 18, these devices can include a memory system 1820 that includes the memory controller 1816 and a memory array(s) 1818, one or more input devices 1822, one or more output devices 1824, one or more network interface devices 1826, and one or more display controllers 1828, as examples. The memory system 1820 can be provided in an IC package 1802(2) that includes a package substrate with the embedded capacitor package 1804(2). The network interface devices 1826 can be provided in an IC package 1802(3) that includes a package substrate with the embedded capacitor package 1804(3). Each of the memory system 1820, the one or more input devices 1822, the one or more output devices 1824, the one or more network interface devices 1826, and the one or more display controllers 1828 can be provided in the same or different circuit packages. The input devices 1822 and/or the output devices 1824 can be provided in a respective IC package 1802(4), 1802(5) that includes a package substrate with a respective embedded capacitor package 1804(4), 1804(5). The input device(s) 1822 can include any type of input device, including, but not limited to, input keys, switches, voice processors, etc. The output device(s) 1824 can include any type of output device, including, but not limited to, audio, video, other visual indicators, etc. The network interface device(s) 1826 can be any device configured to allow exchange of data to and from a network 1830. The network 1830 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1826 can be configured to support any type of communications protocol desired.

The CPU 1808 may also be configured to access the display controller(s) 1828 over the system bus 1814 to control information sent to one or more displays 1832. The display 1832 can be provided in an IC package 1802(6) that includes a package substrate with the embedded capacitor package 1804(6). The display controller(s) 1828 sends information to the display(s) 1832 to be displayed via one or more video processors 1834, which process the information to be displayed into a format suitable for the display(s) 1832. The display controller(s) 1828 and video processor(s) 1834 can be provided in a respective IC package 1802(7), 1802(8) that includes a package substrate with a respective embedded capacitor package 1804(7), 1804(8), or be provided in the same IC package 1802, or be provided in the same IC package 1802(1) containing the CPU 1808 as an example. The display(s) 1832 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. An integrated circuit (IC), comprising:
   a semiconductor layer comprising:
      a first side and a second side opposite the first side; and
      a plurality of semiconductor devices;
   a signal interconnect structure adjacent to the first side of the semiconductor layer, the signal interconnect structure comprising:
      a plurality of first metal interconnects each configured to transfer an input/output (I/O) signal to a coupled first semiconductor device of the plurality of semiconductor devices;
   a power distribution network (PDN) interconnect structure adjacent to the second side of the semiconductor layer, the PDN interconnect structure comprising:
      a plurality of second metal interconnects each configured to transfer a power signal; and
   a plurality of first vias each extending through the semiconductor layer and each coupled to a second metal interconnect of the plurality of second metal interconnects and the signal interconnect structure.
2. The IC of clause 1, wherein:
   the signal interconnect structure comprises a plurality of first metallization layers comprising:
      the plurality of first metal interconnects; and
      a plurality of second vias interconnecting the plurality of second metal interconnects; and
   the PDN interconnect structure comprises a plurality of second metallization layers comprising:
      the plurality of second metal interconnects; and
      a plurality of third vias interconnecting the plurality of second metal interconnects.
3. The IC of clause 1 or 2, wherein the PDN interconnect structure further comprises a plurality of third metal interconnects; and
further comprising:
   a plurality of second vias each extending through the semiconductor layer and each coupled to a third metal interconnect of the plurality of third metal interconnects and a first metal interconnect of the plurality of first metal interconnects.
4. The IC of clause 3, wherein each of the plurality of third metal interconnects are not coupled to a power signal node.
5. The IC of clause 3 or 4, wherein the PDN interconnect structure further comprises a plurality of third vias each coupled to a second metal interconnect of the plurality of second metal interconnects and a second via of the plurality of second vias.
6. The IC of any of clauses 1-5, further comprising one or more capacitors in the PDN interconnect structure and each coupled to a second metal interconnect of the plurality of second metal interconnects.
7. The IC of clause 6, wherein:
   the PDN interconnect structure comprises a silicon layer; and
   at least one capacitor of the one or more capacitors comprises at least one silicon capacitor in the silicon layer.
8. The IC of clause 7, wherein the at least one silicon capacitor comprises at least one deep trench capacitor (DTC).
9. The IC of clause 6, wherein:
   the PDN interconnect structure comprises a dielectric layer; and
   at least one capacitor of the one or more capacitors comprises at least one dielectric capacitor in the dielectric layer.
10. The IC of clause 9, wherein the dielectric layer comprises a silicon oxide layer.
11. The IC of any of clauses 1-10, further comprising:
   a first die structure comprising the semiconductor layer and the signal interconnect structure; and
   a second die structure comprising the PDN interconnect structure;
   wherein the first die structure is bonded to the second die structure to couple each second metal interconnect of the plurality of second metal interconnects to a first via of the plurality of first vias.
12. The IC of clause 11, further comprising a metal bump layer between the PDN interconnect structure and the semiconductor layer, the metal bump layer comprising a plurality of metal bumps each coupled to a second metal interconnect of the plurality of second metal interconnects and a first via of the plurality of first vias.
13. The IC of clause 11, wherein each second metal interconnect of the plurality of second metal interconnects is directly bonded to a first via of the plurality of first vias.
14. The IC of any of clauses 1-13, wherein:
   the semiconductor layer extends in a first direction;
   the second side is opposite the first side in a second direction orthogonal to the first direction;
   the plurality of first vias each extend through the semiconductor layer in the second direction; and
   a plurality of second vias each extend through the semiconductor layer in the second direction.
15. The IC of any of clauses 1-14, wherein the plurality of first vias comprises a plurality of first through-silicon vias (TSVs).
16. The IC of any of clauses 3-5, wherein the plurality of second vias comprises a plurality of second through-silicon vias (TSVs).
17. The IC of any of clauses 1-16 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
18. A method of fabricating an integrated circuit (IC), comprising:
   forming a semiconductor layer comprising a first side and a second side opposite the first side;
   forming a plurality of semiconductor devices in the semiconductor layer;
   forming a plurality of first vias each extending through the semiconductor layer;
   forming a signal interconnect structure adjacent to the first side of the semiconductor layer, wherein forming the signal interconnect structure further comprises:
      forming a plurality of first metal interconnects each configured to transfer an input/output (I/O) signal to a coupled first semiconductor device of the plurality of semiconductor devices;
   forming a power distribution network (PDN) interconnect structure, wherein forming the PDN interconnect structure further comprises:
      forming a plurality of second metal interconnects each configured to transfer a power signal;
   coupling the PDN interconnect structure adjacent to the second side of the semiconductor layer, coupling each second metal interconnect of the plurality of second metal interconnects to a first via of the plurality of first vias.
19. The method of clause 18, further comprising forming a plurality of second vias each extending through the semiconductor layer;
   wherein:
      forming the signal interconnect structure adjacent to the first side of the semiconductor layer further comprises coupling the signal interconnect structure to each second via of the plurality of second vias;
      forming the PDN interconnect structure further comprises forming a plurality of third metal interconnects in the PDN interconnect structure; and
      coupling the PDN interconnect structure adjacent to the second side of the semiconductor layer further comprises coupling each third metal interconnect of the plurality of third metal interconnects to a second via of the plurality of second vias.
20. The method of clause 19, further comprising not coupling the plurality of third metal interconnects to a power signal node.
21. The method of any of clauses 18-20, further comprising:
   disposing one or more capacitors in the PDN interconnect structure; and
   coupling each capacitor of the one or more capacitors to a second metal interconnect of the plurality of second metal interconnects.
22. The method of clause 21, wherein:
   forming the PDN interconnect structure further comprises forming a silicon layer in the PDN interconnect structure; and
   disposing the one or more capacitors in the PDN interconnect structure further comprises disposing at least one silicon capacitor of the one or more capacitors in the silicon layer.
23 The method of clause 21, wherein:
   forming the PDN interconnect structure further comprises forming a dielectric layer in the PDN interconnect structure; and
   disposing the one or more capacitors in the PDN interconnect structure further comprises disposing at least one dielectric capacitor of the one or more capacitors in the dielectric layer.
24 The method of any of clauses 18-23, further comprising:
   forming a first wafer comprising:
      forming the semiconductor layer comprising the first side and the second side opposite the first side;
      forming the plurality of semiconductor devices each comprising the I/O terminal in the semiconductor layer;
      forming the plurality of first vias each extending through the semiconductor layer; and
      forming the signal interconnect structure adjacent to the first side of the semiconductor layer, the signal interconnect structure comprising:
         the plurality of first metal interconnects each coupled to an I/O terminal of the first semiconductor device of the plurality of semiconductor devices; and
   forming a second wafer comprising:
      forming the PDN interconnect structure comprising the plurality of second metal interconnects each coupled to a power signal node;
   wherein:
      coupling the PDN interconnect structure adjacent to the second side of the semiconductor layer comprises coupling the second wafer structure to the first wafer structure coupling each second metal interconnect of the plurality of second metal interconnects to a first via of the plurality of first vias to form a combined wafer structure.
25. The method of clause 24, wherein:
   forming the second wafer structure further comprises forming a metal bump layer comprising a plurality of metal bumps each coupled to a second metal interconnect of the plurality of second metal interconnects; and
   coupling the second wafer structure to the first wafer structure comprises coupling each metal bump of the plurality of metal bumps to a first via of the plurality of first vias.
26. The method of clause 24, wherein coupling the second wafer structure to the first wafer structure comprises directly bonding each second metal interconnect of the plurality of second metal interconnects to a first via of the plurality of first vias.
27. The method of any of clauses 24-26, further comprising dicing the combined wafer structure to form the IC.
28. A three-dimensional (3D) integrated circuit (IC) (3DIC), comprising:
   a first IC, comprising:
      a first semiconductor layer comprising:
         a first side and a second side opposite the first side; and
         a plurality of first semiconductor devices;
      a signal interconnect structure adjacent to the first side of the first semiconductor layer, the signal interconnect structure comprising:
         a plurality of first metal interconnects each configured to transfer an input/output (I/O) signal to a coupled first semiconductor device of the plurality of first semiconductor devices;
      a power distribution network (PDN) interconnect structure adjacent to the second side of the first semiconductor layer, the PDN interconnect structure comprising:
         a plurality of second metal interconnects each configured to transfer a power signal; and
      a plurality of first vias each extending through the first semiconductor layer and each coupled to a second metal interconnect of the plurality of second metal interconnects and the signal interconnect structure; and
   a second IC, comprising:
      a second semiconductor layer;
      a third interconnect structure adjacent to the second semiconductor layer, the third interconnect structure comprising:
         a plurality of third metal interconnects each comprising a power signal node; and
      a plurality of second vias each extending through the second semiconductor layer and each coupled to a third metal interconnect of the plurality of third metal interconnects;
   wherein:
      the first IC is coupled to the second IC, by each of the plurality of second metal interconnects in the second IC being coupled to a second via of the plurality of second vias in the first IC to couple each of the plurality of second metal interconnects to a third metal interconnect of the plurality of third metal interconnects in the second IC.
29. The 3DIC of clause 28, further comprising one or more capacitors in the PDN interconnect structure of the first IC and each coupled to a second metal interconnect of the plurality of second metal interconnects in the first IC.
30. The 3DIC of clause 29, wherein at least one capacitor of the one or more capacitors in the PDN interconnect structure of the first IC are each further coupled to a second via of the plurality of second vias in the second IC to couple the at least one capacitor to at least one third metal interconnect of plurality of third metal interconnects.

What is claimed is:

1. An integrated circuit (IC), comprising:
a semiconductor layer comprising:
a first side and a second side opposite the first side; and
a plurality of semiconductor devices;
a signal interconnect structure adjacent to the first side of the semiconductor layer, the signal interconnect structure comprising:
a plurality of first metal interconnects each configured to transfer an input/output (I/O) signal to a coupled first semiconductor device of the plurality of semiconductor devices;
a power distribution network (PDN) interconnect structure adjacent to the second side of the semiconductor layer, the PDN interconnect structure comprising:
a plurality of second metal interconnects each configured to transfer a power signal; and
a plurality of first vias each extending through the semiconductor layer and each coupled to a second metal interconnect of the plurality of second metal interconnects and the signal interconnect structure.

2. The IC of claim 1, wherein:
the signal interconnect structure comprises a plurality of first metallization layers comprising:
the plurality of first metal interconnects; and
a plurality of second vias interconnecting the plurality of second metal interconnects; and
the PDN interconnect structure comprises a plurality of second metallization layers comprising:
the plurality of second metal interconnects; and
a plurality of third vias interconnecting the plurality of second metal interconnects.

3. The IC of claim 1, wherein the PDN interconnect structure further comprises a plurality of third metal interconnects; and
further comprising:
a plurality of second vias each extending through the semiconductor layer and each coupled to a third metal interconnect of the plurality of third metal interconnects and a first metal interconnect of the plurality of first metal interconnects.

4. The IC of claim 3, wherein each of the plurality of third metal interconnects are not coupled to a power signal node.

5. The IC of claim 3, wherein the PDN interconnect structure further comprises a plurality of third vias each coupled to a second metal interconnect of the plurality of second metal interconnects and a second via of the plurality of second vias.

6. The IC of claim 1, further comprising one or more capacitors in the PDN interconnect structure and each coupled to a second metal interconnect of the plurality of second metal interconnects.

7. The IC of claim 6, wherein:
the PDN interconnect structure comprises a silicon layer; and
at least one capacitor of the one or more capacitors comprises at least one silicon capacitor in the silicon layer.

8. The IC of claim 7, wherein the at least one silicon capacitor comprises at least one deep trench capacitor (DTC).

9. The IC of claim 6, wherein:
the PDN interconnect structure comprises a dielectric layer; and
at least one capacitor of the one or more capacitors comprises at least one dielectric capacitor in the dielectric layer.

10. The IC of claim 9, wherein the dielectric layer comprises a silicon oxide layer.

11. The IC of claim 1, further comprising:
a first die structure comprising the semiconductor layer and the signal interconnect structure; and
a second die structure comprising the PDN interconnect structure;
wherein the first die structure is bonded to the second die structure to couple each second metal interconnect of the plurality of second metal interconnects to a first via of the plurality of first vias.

12. The IC of claim 11, further comprising a metal bump layer between the PDN interconnect structure and the semiconductor layer, the metal bump layer comprising a plurality of metal bumps each coupled to a second metal interconnect of the plurality of second metal interconnects and a first via of the plurality of first vias.

13. The IC of claim 11, wherein each second metal interconnect of the plurality of second metal interconnects is directly bonded to a first via of the plurality of first vias.

14. The IC of claim 1, wherein:
the semiconductor layer extends in a first direction;
the second side is opposite the first side in a second direction orthogonal to the first direction;
the plurality of first vias each extend through the semiconductor layer in the second direction; and
a plurality of second vias each extend through the semiconductor layer in the second direction.

15. The IC of claim 1, wherein the plurality of first vias comprises a plurality of first through-silicon vias (TSVs).

16. The IC of claim 3, wherein the plurality of second vias comprises a plurality of second through-silicon vias (TSVs).

17. The IC of claim 1 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

18. A method of fabricating an integrated circuit (IC), comprising:
forming a semiconductor layer comprising a first side and a second side opposite the first side;
forming a plurality of semiconductor devices in the semiconductor layer;
forming a plurality of first vias each extending through the semiconductor layer;
forming a signal interconnect structure adjacent to the first side of the semiconductor layer, wherein forming the signal interconnect structure further comprises:
forming a plurality of first metal interconnects each configured to transfer an input/output (I/O) signal to a coupled first semiconductor device of the plurality of semiconductor devices;
forming a power distribution network (PDN) interconnect structure, wherein forming the PDN interconnect structure further comprises:
forming a plurality of second metal interconnects each configured to transfer a power signal;
coupling the PDN interconnect structure adjacent to the second side of the semiconductor layer, coupling each second metal interconnect of the plurality of second metal interconnects to a first via of the plurality of first vias.

19. The method of claim 18, further comprising forming a plurality of second vias each extending through the semiconductor layer;
wherein:
forming the signal interconnect structure adjacent to the first side of the semiconductor layer further comprises coupling the signal interconnect structure to each second via of the plurality of second vias;
forming the PDN interconnect structure further comprises forming a plurality of third metal interconnects in the PDN interconnect structure; and
coupling the PDN interconnect structure adjacent to the second side of the semiconductor layer further comprises coupling each third metal interconnect of the plurality of third metal interconnects to a second via of the plurality of second vias.

20. The method of claim 19, further comprising not coupling the plurality of third metal interconnects to a power signal node.

21. The method of claim 18, further comprising:
disposing one or more capacitors in the PDN interconnect structure; and
coupling each capacitor of the one or more capacitors to a second metal interconnect of the plurality of second metal interconnects.

22. The method of claim 21, wherein:
forming the PDN interconnect structure further comprises forming a silicon layer in the PDN interconnect structure; and
disposing the one or more capacitors in the PDN interconnect structure further comprises disposing at least one silicon capacitor of the one or more capacitors in the silicon layer.

23. The method of claim 21, wherein:
forming the PDN interconnect structure further comprises forming a dielectric layer in the PDN interconnect structure; and
disposing the one or more capacitors in the PDN interconnect structure further comprises disposing at least one dielectric capacitor of the one or more capacitors in the dielectric layer.

24. The method of claim 18, further comprising:
forming a first wafer comprising:
forming the semiconductor layer comprising the first side and the second side opposite the first side;
forming the plurality of semiconductor devices each comprising the I/O terminal in the semiconductor layer;
forming the plurality of first vias each extending through the semiconductor layer; and
forming the signal interconnect structure adjacent to the first side of the semiconductor layer, the signal interconnect structure comprising:
the plurality of first metal interconnects each coupled to an I/O terminal of the first semiconductor device of the plurality of semiconductor devices; and
forming a second wafer comprising:
forming the PDN interconnect structure comprising the plurality of second metal interconnects each coupled to a power signal node;
wherein:
coupling the PDN interconnect structure adjacent to the second side of the semiconductor layer comprises coupling the second wafer structure to the first wafer structure coupling each second metal interconnect of the plurality of second metal interconnects to a first via of the plurality of first vias to form a combined wafer structure.

25. The method of claim 24, wherein:
forming the second wafer structure further comprises forming a metal bump layer comprising a plurality of metal bumps each coupled to a second metal interconnect of the plurality of second metal interconnects; and
coupling the second wafer structure to the first wafer structure comprises coupling each metal bump of the plurality of metal bumps to a first via of the plurality of first vias.

26. The method of claim 24, wherein coupling the second wafer structure to the first wafer structure comprises directly bonding each second metal interconnect of the plurality of second metal interconnects to a first via of the plurality of first vias.

27. The method of claim 24, further comprising dicing the combined wafer structure to form the IC.

28. A three-dimensional (3D) integrated circuit (IC) (3DIC), comprising:
a first IC, comprising:
a first semiconductor layer comprising:
a first side and a second side opposite the first side; and
a plurality of first semiconductor devices;
a signal interconnect structure adjacent to the first side of the first semiconductor layer, the signal interconnect structure comprising:
a plurality of first metal interconnects each configured to transfer an input/output (I/O) signal to a coupled first semiconductor device of the plurality of first semiconductor devices;
a power distribution network (PDN) interconnect structure adjacent to the second side of the first semiconductor layer, the PDN interconnect structure comprising:
a plurality of second metal interconnects each configured to transfer a power signal; and
a plurality of first vias each extending through the first semiconductor layer and each coupled to a second metal interconnect of the plurality of second metal interconnects and the signal interconnect structure; and
a second IC, comprising:
a second semiconductor layer;
a third interconnect structure adjacent to the second semiconductor layer, the third interconnect structure comprising:
a plurality of third metal interconnects each comprising a power signal node; and
a plurality of second vias each extending through the second semiconductor layer and each coupled to a third metal interconnect of the plurality of third metal interconnects;
wherein:
the first IC is coupled to the second IC, by each of the plurality of second metal interconnects in the second IC being coupled to a second via of the plurality of second vias in the first IC to couple each of the plurality of second metal interconnects to a third metal interconnect of the plurality of third metal interconnects in the second IC.

29. The 3DIC of claim 28, further comprising one or more capacitors in the PDN interconnect structure of the first IC and each coupled to a second metal interconnect of the plurality of second metal interconnects in the first IC.

30. The 3DIC of claim 29, wherein at least one capacitor of the one or more capacitors in the PDN interconnect structure of the first IC are each further coupled to a second via of the plurality of second vias in the second IC to couple the at least one capacitor to at least one third metal interconnect of plurality of third metal interconnects.
